(19) United States
(12) Patent Application Publication
(10) Pub. No.: US 2022/0405057 A1
(43) Pub. Date: Dec. 22, 2022

(54) SEMICONDUCTOR INTEGRATED CIRCUIT AND ARITHMETIC LOGIC OPERATION SYSTEM

(71) Applicant: Kioxia Corporation, Tokyo (JP)

(72) Inventors: Radu BERDAN, Shinagawa (JP); Daisuke MIYASHITA, Kawasaki (JP); Jun DEGUCHI, Kawasaki (JP)

(73) Assignee: Kioxia Corporation, Tokyo (JP)

(21) Appl. No.: 17/643,697

(22) Filed: Dec. 10, 2021

(30) Foreign Application Priority Data
Jun. 22, 2021 (JP) 2021-102877

(51) Int. Cl. G06F 7/57; G06F 7/544; G06F 7/523; G06F 7/50; H03M 1/34

(52) U.S. Cl. CPC G06F 7/57; G06F 7/5443; G06F 7/523; G06F 7/50; H03M 1/34

(57) ABSTRACT

According to one embodiment, in a semiconductor integrated circuit, the plurality of storage devices are arranged in a form of a plurality of rows. Each of the storage devices are configured to store a bit position value of a weight of multiple bits. The plurality of multiplication circuits are arranged in a form of a plurality of rows and are configured to multiply a plurality of input voltages by the weight of multiple bits to generate a plurality of multiplication results. The one or more capacitive devices are configured to accumulate charges corresponding to the plurality of multiplication results. The adder circuit are configured to generate an output voltage corresponding to the total value of the charges accumulated in the one or more capacitive devices. The plurality of input voltages have different amplitudes. Each of the input voltages is associated with a corresponding bit position of the weight.

### CROSS-REFERENCE TO RELATED APPLICATIONS

This application is based upon and claims the benefit of priority from Japanese Patent Application No. 2021-102877, filed on Jun. 22, 2021; the entire contents of which are incorporated herein by reference.

### FIELD

Embodiments described herein relate generally to a semiconductor integrated circuit and an arithmetic logic operation system.

### BACKGROUND

Semiconductor integrated circuits can execute a sum-of-product operation that adds a plurality of results obtained by multiplying each of a plurality of input values by a weight. In this event, the sum-of-product operation is desired to be efficient.

### BRIEF DESCRIPTION OF THE DRAWINGS

FIG. 1 is a diagram illustrating a configuration of an arithmetic logic operation system including a semiconductor integrated circuit according to a first embodiment;

FIG. 2 is a circuit diagram illustrating the configuration of the semiconductor integrated circuit according to the first embodiment;

FIGS. 3A to 3D are waveform diagrams illustrating an operation of the semiconductor integrated circuit according to the first embodiment;

FIG. 4 is a circuit diagram illustrating a configuration of a semiconductor integrated circuit according to a modification of the first embodiment;

FIG. 5 is a circuit diagram illustrating a configuration of a semiconductor integrated circuit according to a second embodiment;

FIGS. 6A to 6D are waveform diagrams illustrating an operation of the semiconductor integrated circuit according to the second embodiment;

FIGS. 7A to 7D are waveform diagrams illustrating the operation of the semiconductor integrated circuit according to the second embodiment;

FIG. 8 is a circuit diagram illustrating a configuration of a semiconductor integrated circuit according to a third embodiment;

FIG. 9 is a circuit diagram illustrating a schematic configuration of a unit cell according to a fourth embodiment;

FIG. 10 is a circuit diagram illustrating a specific configuration of the unit cell according to the fourth embodiment;

FIG. 11 is a circuit diagram illustrating a specific configuration of a unit cell according to a modification of the fourth embodiment;

FIG. 12 is a circuit diagram illustrating a unit configuration of an input circuit according to a fifth embodiment;

FIG. 13 is a circuit diagram illustrating a configuration of an input circuit according to the fifth embodiment;

FIG. 14 is a circuit diagram illustrating a use case of the input circuit according to the fifth embodiment;

FIG. 15 is a circuit diagram illustrating another use case of the input circuit according to the fifth embodiment;

FIG. 16 is a circuit diagram illustrating a configuration of an input circuit according to a modification of the fifth embodiment;

FIG. 17 is a circuit diagram illustrating a unit configuration of an input circuit according to a sixth embodiment;

FIG. 18 is a circuit diagram illustrating a configuration of a D/A converter according to the sixth embodiment;

FIG. 19 is a diagram illustrating a mapping table according to the sixth embodiment;

FIG. 20 is a circuit diagram illustrating a configuration of an input circuit according to the sixth embodiment; and

FIGS. 21A and 21B are waveform diagrams illustrating an operation of the input circuit according to the sixth embodiment.

### DETAILED DESCRIPTION

In general, according to one embodiment, there is provided a semiconductor integrated circuit including a plurality of storage devices, a plurality of multiplication circuits, one or more capacitive devices and an adder circuit. The plurality of storage devices are arranged in a form of a plurality of rows. Each of the storage devices are configured to store a bit position value of a weight of multiple bits. The plurality of multiplication circuits are arranged in a form of a plurality of rows. The plurality of multiplication circuits are configured to multiply a plurality of input voltages by the weight of multiple bits to generate a plurality of multiplication results. The one or more capacitive devices are configured to accumulate charges corresponding to the plurality of multiplication results. The adder circuit are configured to generate an output voltage corresponding to the total value of the charges accumulated in the one or more capacitive devices. The plurality of input voltages have different amplitudes. Each of the input voltages is associated with a corresponding bit position of the weight.

Exemplary embodiments of an arithmetic logic operation system will be explained below in detail with reference to the accompanying drawings. The present invention is not limited to the following embodiments.

### First Embodiment

An arithmetic logic operation system according to a first embodiment can be used, for example, to execute a part of a processing of a neural network, such as artificial intelligence (AI) accelerators. The AI accelerator executes a sum-of-product operation that multiplies a multi-bit input by a multi-bit weight and adds results of the multiplication, for learning a task or making an inference. The arithmetic logic operation system needs to perform such an arithmetic logic operation in parallel at high speed and with efficiency. In one example, the arithmetic logic operation system performs the sum-of-product operation in parallel for a plurality of neurons in a given layer in a neural network (parallel operation). The parallel operation includes a multiplication operation between a multi-bit input and a multi-bit weight with optional bit precision.

The parallel operation may be implemented in hardware by a semiconductor integrated circuit of a configuration in which a memory circuit and an arithmetic logic operation circuit are arranged integrally or physically close to each other. The semiconductor integrated circuit has a weight that is set fixedly rather than dynamically for multiplication. Such configuration of the semiconductor integrated circuit includes a digital-based configuration, an analog current-based configuration, an analog charge-based configuration, and the like.

In the digital-based configuration, the calculation is executed in a memory device by performing the arithmetic logic operation corresponding to a weight bit for an input bit in a bit-wise logical operation circuit arranged in the memory. The analog current-based configuration applies a voltage to each row of the array of variable resistive devices (or elements) with programmed weights and adds current values using Kirchhoff's law.

On the other hand, the analog charge-based configuration performs the arithmetic logic operation for a logical product of multiple bits of the input and multiple bits of the weight in parallel on a bit-by-bit basis and causes a voltage corresponding to a result obtained by performing the arithmetic logic operation for the multiple bits to be held in a plurality of capacitive devices (or elements) of a capacitive array. Then, it sequentially reads out the charges of the plurality of capacitive devices in the capacitive array and performs analog-to-digital (A/D) conversion to generate a digital signal, while performing the addition of digital signal by repeating the bit shift and adding the digital signals.

The analog charge-based configuration is superior to the digital-based configuration in that the arithmetic logic operation rate is faster upon performing the arithmetic logic operation with medium precision of bits. The analog charge-based configuration is superior to the analog current-based configuration in that easily reducible influence of variation between devices.

However, in the analog charge-based configuration, the bit shift operation for the addition of signals is performed for the number of times proportional to the number of bits of at least one of an input and a weight. Thus, the increase in the number of bits of at least one of an input and a weight is more likely to cause a decrease in the parallel operation efficiency. The processing time required for the parallel operation is more likely to increase depending on the bit precision of at least one of an input and a weight.

Thus, according to the present embodiment, the semiconductor integrated circuit multiplies a plurality of input voltages having a positive signal amplitude by a weight of multiple bits representing a positive integer and generates an output voltage corresponding to an addition result based on the charges corresponding to a plurality of multiplication results. This makes it possible to improve the parallel operation efficiency regardless of the bit precision of any one of input or weight, intending to obtain fixed processing time of parallel operation.

The semiconductor integrated circuit converts each bit of the digital input data into a plurality of input voltages by digital-to-analog (D/A) conversion or the like. The semiconductor integrated circuit multiplies a plurality of input voltages by a weight of multiple bits. The semiconductor integrated circuit generates an output voltage corresponding to the addition result on the basis of the plurality of multiplication results. In one example, the output voltage can be a voltage corresponding to the charge obtained by accumulating a plurality of multiplication results in parallel in a plurality of capacitive devices and collectively redistributing the charges of the plurality of capacitive devices so that the accumulated voltages are averaged. Thus, it is possible to obtain the addition result without performing the bit shift and to improve the efficiency of parallel operation regardless of the bit precision of any one of input or weight, obtaining fixed processing time of parallel operation.

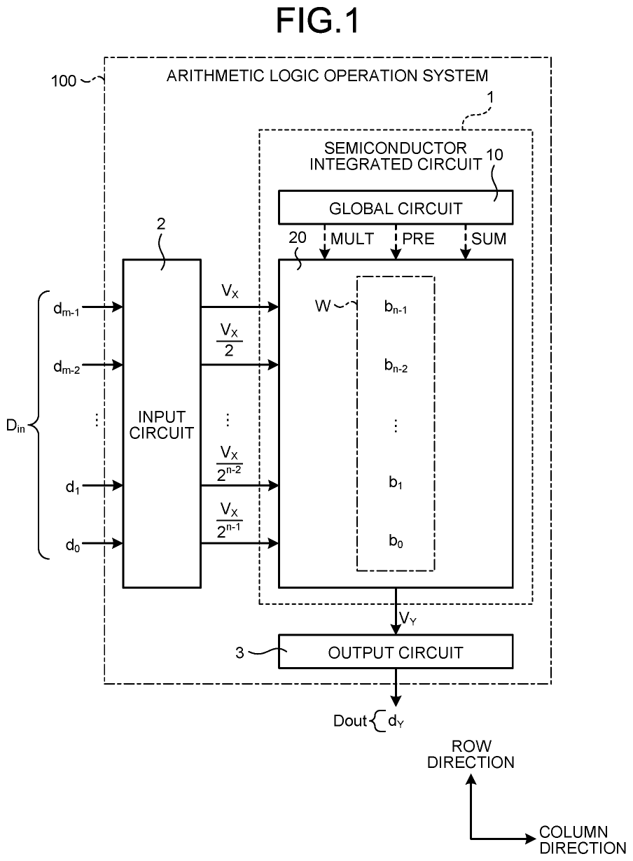

An arithmetic logic operation system 100 including a semiconductor integrated circuit 1 can be configured as illustrated in FIG. 1. FIG. 1 is a diagram illustrating a configuration of the arithmetic logic operation system 100 including the semiconductor integrated circuit 1. The arithmetic logic operation system 100 includes an input circuit 2, the semiconductor integrated circuit 1, and an output circuit 3. The arithmetic logic operation system 100 supports a multi-bit input, and it is possible to receive m-bit input data Dₘ₋₁, dₘ₋₂, . . . , d₁, d₀) through the input circuit 2. Here, m is any integer greater than or equal to 1. Each element included in the input data Dᵢₙ is a digital signal having one bit. In the following, the description is made mainly assuming the case where m =n, but m≠n can be used. In the case where m n, the input circuit 2 is assumed to be configured to convert m-bit input data Dᵢₙ into n analog voltages. In one example, the input circuit 2 includes a digital-to-analog (D/A) converter. The D/A converter can be configured in such a way that the number of input nodes is m and the number of output nodes is n. It should be noted that m has no connection to n and they can be different or the same, it doesn't matter.

The arithmetic logic operation system 100 multiplies the input data Dᵢₙ=(dₘ₋₁, dₘ₋₂, . . . , d₁, d₀) having m bits d and a weight vector W=(bₙ₋₁, bₙ₋₂, . . . , b₁, b₀) having n bits b and outputs data Dₒᵤₜ to be output according to the multiplication results, where n is any integer greater than or equal to 1. The number of bits n of the weight vector W can be equal to the number of bits m of the input data Dᵢₙ. It should be noted that this is not important for this embodiment.

In other words, in the arithmetic logic operation system 100, the input circuit 2 converts the digital domain input data Dᵢₙ=(dₘ₋₁, dₘ₋₂, . . . , d₁, d₀) into an analog domain input vector X=(V_{X}, V_{X}/2, . . . , V_{X}/2ⁿ⁻², V_{X}/2ⁿ⁻¹) by D/A conversion or the like and inputs the result to the semiconductor integrated circuit 1. In other words, the input vector X includes n input voltages V_{X}, V_{X}/2, . . . , V_{X}/2ⁿ⁻², V_{X}/2ⁿ⁻¹. The semiconductor integrated circuit 1 has the preset weight vector W=(bₙ₋₁, bₙ₋₂, . . . , b₁, b₀). Each element of the weight vector W is a digital signal having one bit. The n-bit pattern “bₙ₋₁, bₙ₋₂, . . . , b₁, b₀” of the weight vector W represents a positive integer. In the following description, the weight vector W is also simply referred to as a weight W. The n input voltages included in the input vector X correspond to n bits of the weight W. Each input voltage included in the input vector X is an analog signal having a positive signal amplitude corresponding to the position of the corresponding bit of the weight W. A global circuit 10 generates global signals MULT, PRE, and SUM and supplies the signals to an arithmetic logic operation circuit 20.

The semiconductor integrated circuit 1 performs the arithmetic logic operation for the scalar product between the input vector X=(V_{X}, V_{X}/2, . . . , V_{X}/2ⁿ⁻², V_{X}/2ⁿ⁻¹) and the weight vector W=bₙ₋₁, bₙ₋₂, . . . , b₁, b₀) on the basis of the global signals MULT, PRE, and SUM and inputs an output voltage Y=X·W=V_{Y} as the arithmetic logic operation result to the output circuit 3. The output voltage Y=V_{Y} is an analog signal. The output circuit 3 converts the output voltage V_{Y} into data Dₒᵤₜ to be output by A/D conversion or the like and outputs the converted result. The output data Dₒᵤₜ is a digital signal including one or more bits.

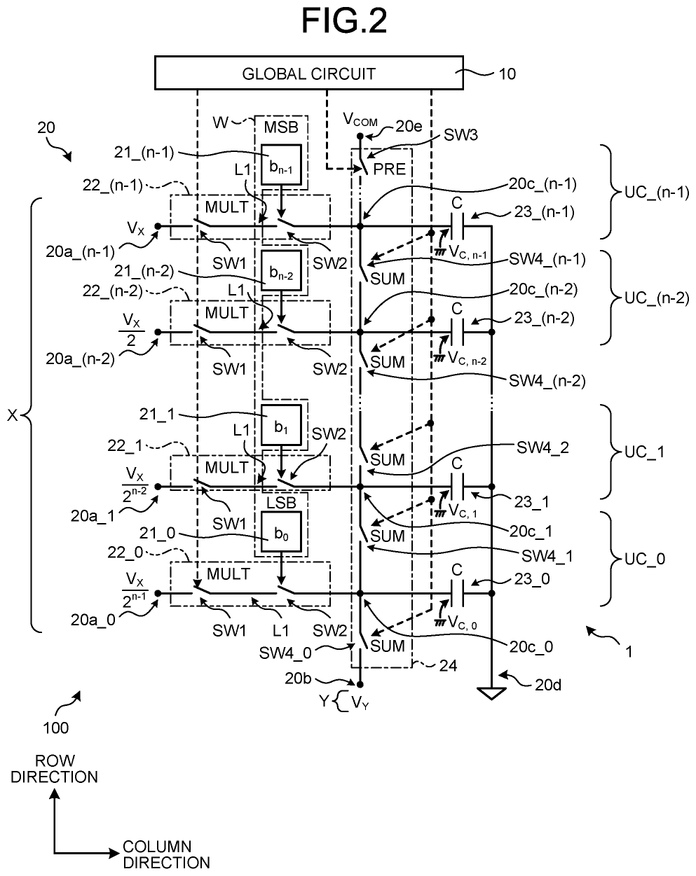

The semiconductor integrated circuit 1 can be configured as illustrated in FIG. 2. FIG. 2 is a circuit diagram illustrating the configuration of the semiconductor integrated circuit 1.

The semiconductor integrated circuit 1 has the global circuit 10 and the arithmetic logic operation circuit 20. The arithmetic logic operation circuit 20 receives n input voltages V_{X}, . . . , V_{X}/2ⁿ⁻¹ at a plurality of input nodes 20a_(n−1), . . . , 20a_0, respectively. The n input voltages V_{X}, . . . , V_{X}/2ⁿ⁻¹ are included in the input vector X. The input voltages V_{X}, . . . , V_{X}/2ⁿ⁻¹ are applied to the respective corresponding input nodes 20a_(n−1), . . . , 20a_0. Here, n is the bit precision of the weight. The global circuit 10 generates global signals MULT, PRE, and SUM and supplies the signals to the arithmetic logic operation circuit 20. The arithmetic logic operation circuit 20 performs the arithmetic logic operation corresponding to the global signals MULT, PRE, and SUM and outputs the output voltage V_{Y} as the arithmetic logic operation result from the output node 20b.

The arithmetic logic operation circuit 20 includes n storage devices 21 (n−1) to 21_0, a plurality of multiplication circuits 22 (n−1) to 22_0, n capacitive devices 23_(n−1) to 23_0, and an adder circuit 24, as illustrated in FIG. 2. FIG. 2 illustrates the configuration of only one column of the arithmetic logic operation circuit 20, but the arithmetic logic operation circuits 20 can be provided with the configuration of a plurality of columns illustrated in FIG. 2.

The n storage devices 21_(n−1) to 21_0 representing an n bit weight are arranged in the form of n row lines (i.e., row lines (n−1) to 0). The n storage devices 21_(n−1) to 21_0 store the n-bit weight W. The n storage devices 21_(n−1) to 21_0 correspond to the bits bₙ₋₁, . . . , b₀ included in the weight W, respectively. The storage devices 21 store and output the respective corresponding bit values of the respective corresponding weights W. The storage device 21 (n−1) stores the value of bit bₙ₋₁ and outputs a voltage corresponding to the value of bit bₙ₋₁. The storage device 21_0 stores the value of bit b₀ and outputs a voltage corresponding to the stored value of bit b₀. The n-bit pattern “bₙ₋₁, bₙ₋₂, . . . , b₁, b₀” included in the weight W represents positive integers.

The n multiplication circuits 22_(n−1) to 22_0 are arranged in the form of n row lines (i.e., row lines (n−1) to 0). The n multiplication circuits 22_(n−1) to 22_0 are connected in parallel to the n input nodes 20a_(n−1) to 20a_0 and the output node 20b via n intermediate nodes 20c_(n−1) to 20c_0, respectively. Each multiplication circuit 22 has a first end connected to the input node 20a and a second end connected to the intermediate node 20c. Each multiplication circuit 22 has a first control terminal that receives the global signal MULT and a second control terminal that receives the output of the storage device 21.

The n multiplication circuits 22_(n−1) to 22_0 equivalently multiply n input voltages by the n-bit weight W to generate n multiplication results. The n multiplication circuits 22_(n−1) to 22_0 correspond to n input voltages and to n bits included in the weight W. Each multiplication circuit 22 equivalently multiplies the corresponding analog signal by the corresponding bit of the weight W to generate a multiplication result. The multiplication circuit 22_(n−1) equivalently multiplies the input signal V_{X} by the value of bit bₙ₋₁ to generate a multiplication result (V_{X})×bₙ₋₁. The multiplication circuit 22_0 equivalently multiplies the input signal V_{X}/2ⁿ⁻¹ by the value of bit b₀ to generate a multiplication result (V_{X}/2ⁿ⁻¹)×b₀.

Each multiplication circuit 22 includes a series connection of a switch SW1 and a switch SW2 between the input node 20a and the intermediate node 20c. The switch SW1 turns ON or OFF depending on the global signal MULT. The switch SW2 remains ON or OFF depending on the bit value of the weight W. The switches SW1 and SW2 are an example of a switching device and are only necessary to be constituted of, for example, a transistor. FIG. 2 illustrates a configuration in which the switch SW1 is connected to the side of the input node 20a between the input node 20a and the intermediate node 20c and the switch SW2 is connected to the side of the intermediate node 20c. However, the switch SW1 can be connected to the side of the intermediate node 20c, and the switch SW2 can be connected to the side of the input node 20a.

The switch SW1 of each of the n multiplication circuits 22_(n−1) to 22_0 turns ON when an active level global signal MULT is received from the global circuit 10 at its control terminal and electrically connects the input node 20a and the first end of the switch SW2. The switch SW1 of each of the n multiplication circuits 22_(n−1) to 22_0 turns OFF when a non-active level global signal MULT is received from the global circuit 10 at its control terminal and electrically cuts off the input node 20a and the first end of the switch SW2.

The n multiplication circuits 22_(n−1) to 22_0 respectively correspond to the n storage devices 21_(n−1) to 21_0. The switches SW2 of the n multiplication circuits 22_(n−1) to 22_0 remain ON or OFF depending on the bit value of the weight W output from the respectively corresponding storage devices 21.

The switch SW2 of the multiplication circuit 22_(n−1) remains ON in the case where the value of the bit bₙ₋₁ of the weight W output from the storage device 21_(n−1) is 1. In this case, when the switch SW1 turns ON, the input node 20a_(n−1) and the intermediate node 20c_(n−1) are electrically connected.

The switch SW2 of the multiplication circuit 22_(n−1) remains OFF in the case where the value of the bit of the weight W output from the storage device 21_(n−1) is 0. In this case, even if the switch SW1 turns ON, the input node 20a_(n−1) and the intermediate node 20c_(n−1) remains electrically cut off.

The switch SW2 of the multiplication circuit 22_0 remains ON in the case where the value of the bit b₀ of the weight W output from the storage device 21_0 is 1. In this case, when the switch SW1 turns ON, the input node 20a_0 and the intermediate node 20c_0 are electrically connected.

The switch SW2 of the multiplication circuit 22_0 remains OFF in the case where the value of the bit b₀ of the weight W output from the storage device 21_0 is 0. In this case, even if the switch SW1 turns ON, the input node 20a_0 and the intermediate node 20c_0 remains electrically cut off.

The n capacitive devices 23_(n−1) to 23_0 are arranged in the form of n row lines (i.e., row lines (n−1) to 0). The n capacitive devices 23_(n−1) to 23_0 respectively correspond to the n storage devices 21_(n−1) to 21_0 and the n multiplication circuits 22_(n−1) to 22 0. The n capacitive devices 23_(n−1) to 23_0 are connected in parallel between the n intermediate nodes 20c_(n−1) to 20c_0 and a reference node 20d, respectively.

The capacitive devices 23 can have a capacitance value C equal to each other. Each of the capacitive devices 23 has a first end connected to the intermediate node 20c and a second end connected to the reference node 20d. The first end of each capacitive device 23 is connected to the corresponding multiplication circuit 22 via the intermediate node 20c. The reference node 20d is supplied with a reference voltage (e.g., the ground voltage of the arithmetic logic operation circuit 20). The reference node 20d can be shared for the n capacitive devices 23_(n−1) to 23_0.

Each of the multiplication circuits 22 changes whether or not to supply the first end of the capacitive device 23 with the input signal depending on the bit value of the weight W. Thus, equivalently, the n multiplication circuits 22_(n−1) to 22_0 multiply the n input voltages by the weight W of n bits.

The adder circuit 24 is arranged between the n multiplication circuits 22_(n−1) to 22_0 and the n capacitive devices 23_(n−1) to 23_0. The adder circuit 24 redistributes the charges accumulated in the n capacitive devices 23_(n−1) to 23_0 depending on the capacitance ratio and generates the output voltage V. The output voltage V_{Y} corresponds to the addition result obtained by adding n multiplication results. The n capacitive devices 23_(n−1) to 23_0 have capacitance values C equal to each other, so the output voltage V_{Y} corresponds to a voltage obtained by averaging the n voltages as n multiplication results. The output voltage V_{Y} can be converted into the addition result by multiplying the value by the number of capacitive devices (i.e., n).

The adder circuit 24 has a switch SW3 between a common node 20e and at least one of the intermediate nodes 20c_(n−1) to 20c_0. FIG. 2 illustrates the configuration in which the switch SW3 is provided between the common node 20e and the intermediate node 20c_(n−1), and the operation in that case is described below. The common node 20e is supplied with a common voltage V_{COM}. The common node 20e can be shared for the n capacitive devices 23_(n−1) to 23_0. The intermediate node 20c_(n−1) is connected to the first end of the capacitive device 23_(n−1). The capacitive device 23_(n−1) is a capacitive device arranged at the position farthest from the output node 20b. The switch SW3 turns ON when an active level global signal PRE is received from the global circuit 10 at its control terminal and electrically connects the common voltage V_{COM} to the intermediate node 20c_(n−1). When the switch SW3 receives a non-active level global signal PRE from the global circuit 10 at its control terminal, the switch SW3 turns OFF and electrically cuts off the common voltage V_{COM} from the intermediate node 20c_(n−1). The switch SW3 is an example of a switching device and is only necessary to be constituted of, for example, a transistor.

The adder circuit 24 has n switches SW4_(n−1) to SW4_0 between the output node 20b and the n intermediate nodes 20c_(n−1) to 20c_0. The n intermediate nodes 20c_(n−1) to 20c_0 are respectively connected to the first ends of the n capacitive devices 23_(n−1) to 23_0. The n switches SW4_(n−1) to SW4_0, when receiving an active level global signal SUM from the global circuit 10 at their control terminals, turn ON and electrically connect first ends of the n capacitive devices 23_(n−1) to 23_0 to the output node 20b. The n switches SW4_(n−1) to SW4_0, when receiving a non-active level global signal SUM from the global circuit 10 at their control terminals, turn OFF and electrically cut off the first ends of the n capacitive devices 23_(n−1) to 23_0 from the output node 20b. The n switches SW4_(n−1) to SW4_0 are an example of a switching device and are only necessary to be constituted of, for example, a transistor.

Moreover, the configuration including the storage device 21, the multiplication circuit 22, the capacitive device 23, and the switch SW4 in each row will be referred to as a unit cell UC. The unit cell UC_(n−1) in the row line (n−1) includes the storage device 21_(n−1), the multiplication circuit 22 (n−1), the capacitive device (n−1), and the switch SW4_(n−1). The unit cell UC_0 in the row line 0 includes the storage device 21_0, the multiplication circuit 22_0, the capacitive device 23_0, and the switch SW4_0.

The configuration illustrated in FIG. 2 enables the semiconductor integrated circuit 1 to implement multi-bit multiplication on a charge basis. The semiconductor integrated circuit 1 is capable of implementing the charge-based arithmetic logic operation Y=X·W in the following three cycles (1) to (3) regardless of the bit precision of either X or W.

(1) The bit values of the weight W are allocated from the most significant bit (MSB) to the least significant bit (LSB), and each bit value is stored into the storage device 21. The global signals PRE and SUM are set to the active level, and the global signal MULT is set to the non-active level. Accordingly, the charges of the capacitive devices 23_(n−1) to 23_0 are discharged to the common node 20e, and the accumulated voltages of the capacitive devices 23_(n−1) to 23_0 are reset to V_{COM}.

(2) The global signal MULT is set to the active level, and the global signals PRE and SUM are set to the non-active level. Accordingly, in the n unit cells UC_(n−1) to UC_0, the weight W is equivalently multiplied by the input voltage, and the charge corresponding to the multiplication result is accumulated in the first end of each of the capacitive devices 23_(n−1) to 23_0. The multiplication and the charge accumulation in the n unit cells UC_(n−1) to UC_0 are performed in parallel with each other. Thus, the accumulated voltage of each capacitive device 23 becomes V (where i =(n−1) to 0).

(3) The global signal SUM is set to the active level, and the global signals PRE and MULT are set to the non-active level. Accordingly, the charges accumulated in the first ends of the n capacitive devices 23_(n−1) to 23_0 are redistributed depending on the capacitance ratio. The n capacitive devices 23_(n−1) to 23_0 have capacitance values C equal to each other, so the accumulated voltage of each capacitive device 23 becomes an averaged voltage.

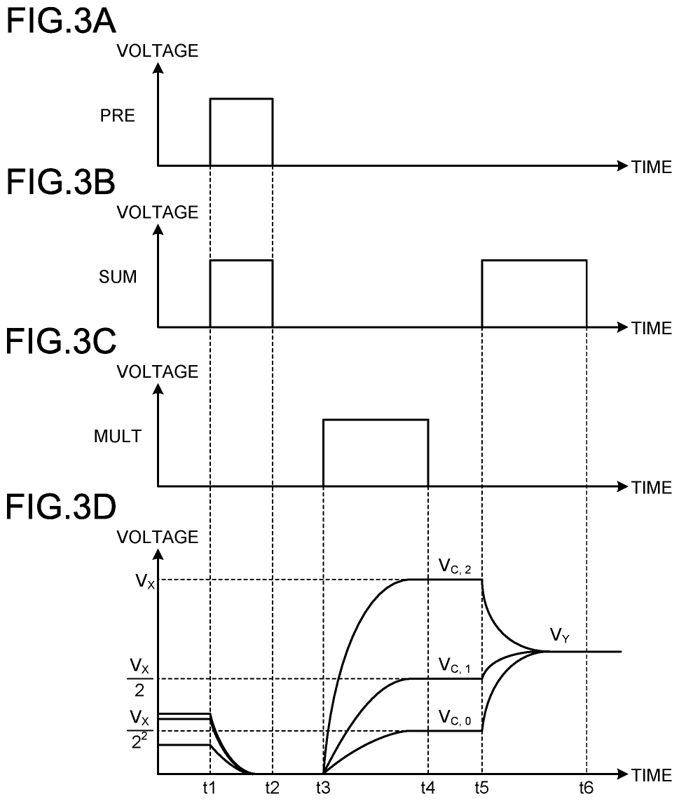

The semiconductor integrated circuit 1 can operate as illustrated in FIGS. 3A to 3D. FIGS. 3A to 3D are waveform diagrams illustrating the operation of the semiconductor integrated circuit 1. FIG. 3A illustrates the temporal transition of levels of the global signal PRE. FIG. 3B illustrates the temporal transition of levels of the global signal SUM. FIG. 3C illustrates the temporal transition of levels of the global signal MULT. FIG. 3D illustrates the temporal variation of the holding voltage of each capacitive device 23.

Immediately before timing tl, the global circuit 10 maintains the global signal PRE, the global signal SUM, and the global signal MULT at respective L levels. The semiconductor integrated circuit 1 is set to the common voltage V_{COM}=0 V (≈ ground potential).

In one example, in the case where n=3 and the weight W=(b₂, b₁, b₀)=(1, 1, 1), the semiconductor integrated circuit 1 stores bit values 1, 1, and 1 in three storage devices 21_2, 21_1, and 21_0, respectively. The multi-bit pattern “111” with the weight W represents a positive integer corresponding to “7” in decimal. The three storage devices 21_2, 21_1, and 21_0 all output an H level that is a logical value corresponding to the bit value 1. Accordingly, all the switches SW2 of three multiplication circuits 22_2, 22_1, and 22_0 remain ON.

The input circuit 2 generates a voltage V_{X} from the 3-bit input data Dᵢₙ=(d₂, d₁, d₀), for example, when m=3, using any method, converts the voltage V_{X} to the input vector X=(V_{X}, V_{X}/2, V_{X}/2²), and inputs the converted result to the semiconductor integrated circuit 1. The three input voltages V_{X}, V_{X}/2, and V_{X}/2² correspond to the multiple bits b₂, b₁, and b₀ included in the weight W, respectively. The input signals V_{X}, V_{X}/2, and V_{X}/2² have positive amplitudes depending on the positions of the respective corresponding bits.

In the row line i, an input signal V_{X,i} given in Formula 1 below is applied to the input node 20a_i. The row line i corresponds to bit b₁ of the weight W. Here, i represents the row line number, also represents the bit position of the weight W, and can have values ranging from n-1 (n is an integer of 2 or more) to 0. In Formula 1, n-1 corresponds to the MSB in multiple bits of the weight W, and 0 corresponds to the LSB.

$$[ Mathematical 1 ]$$

$$row line i {V}_{x , i} = \frac{{V}_{x}}{{2}^{n - i - 1}} \qquad Formula 1$$

In one example, when n=3, in the arithmetic logic operation circuit 20, the input voltage V_{X} is applied to the input node 20a_2 in the row line 2, the input voltage V_{X}/2 is applied to the input node 20a_1 in the row line 1, and the input voltage V_{X}/2² is applied to the input node 20a_0 in the row line 0.

The operation of Cycle (1) is performed during the period from timings t1 to t2. At timing tl, the global circuit 10 shifts and maintains the global signal PRE and the global signal SUM to the H level while maintaining the global signal MULT at the L level. Accordingly, the common voltage V_{COM}=0 V is applied to the first ends of the three capacitive devices 23_2 to 23_0, and the holding voltages V_{C,0} to V_{C,2} of the respective capacitive devices 23_2 to 23_0 are reset to 0 V. In other words, the charges accumulated in the capacitive devices 23_2 to 23_0 are reset. At timing t2, the global circuit 10 shifts the global signal PRE and the global signal SUM to the L level. Accordingly, the reset of the holding voltages V_{C,0} to V_{C,2} of the respective capacitive devices 23_2 to 23_0 is completed.

The operation of Cycle (2) is performed during the period from timings t3 to t4. At timing t3, the global circuit 10 shifts and maintains the global signal MULT to the H level while maintaining the global signal PRE and the global signal SUM at the L level. Accordingly, the multiplication circuit 22_i multiplies the input voltage V_{X,i} by the bit value bᵢ of the weight W. In other words, in the row line i, the switch SW1 of the multiplication circuit 22 i remains ON. In the case where the bit value bᵢ=1 of the weight W stored in the storage device 21_i, the switch SW2 remains ON, and the input voltage V_{X,i} is applied to the first end of the capacitive device 23_i. In the case where the bit value bᵢ=0 of the weight W stored in the storage device 21_i, the switch SW2 remains OFF, and the input voltage V_{X,i} is not applied to the first end of the capacitive device 23_i. Accordingly, in the case where the bit value bᵢ=1 of the weight W, the holding voltage of the capacitive device 23_i increases from 0 V to V_{X,i} gradually. In the case where the bit value bᵢ=0 of the weight W, the holding voltage of the capacitive device 23_i remains 0 V. In other words, a charge Qᵢ corresponding to the result obtained multiplying the input voltage V_{X,i} by the bit value bᵢ of the weight W in the multiplication circuit 22 i is accumulated in the capacitive device 23_i. The charge Qᵢ is given as Formula 2 below.

$$[ Mathematical 2 ]$$

$${Q}_{i} = C \frac{{V}_{X} {b}_{i}}{{2}^{n - i - 1}} \qquad Formula 2$$

In one example, in the case where n=3 and the weight W=(b₂, b₁, b₀)=(1, 1, 1) , the input signal V_{X} is applied to the first end of the capacitive device 23_2 depending on the bit value b₂=1 of the weight W in the row line 2, and the holding voltage V_{C,2} of the capacitive device 23_2 gradually increases from 0 V to V_{X}. Accordingly, the charge Q₂=C×V_{X} is accumulated in the capacitive device 23_2. In the row line 1, the input signal V_{X}/2 is applied to the first end of the capacitive device 23_1 depending on the bit value b₁=1 of the weight W, and the holding voltage V_{C,1} of the capacitive device 23_1 is gradually increased from 0 V to V_{X}/2. Accordingly, the charge Q₁=C×V_{X}/2 is accumulated in the capacitive device 23_1. In the row line 0, the input signal V_{X}/2² is applied to the first end of the capacitive device 23_0 depending on the bit value b₀=1 of the weight W, and the holding voltage Vi2,₀ of the capacitive device 23_0 is gradually increased from 0 V to V_{X}/2². Accordingly, the charge Q₁=C×V_{X}/2² is accumulated in the capacitive device 23_0.

At timing t4, the global circuit 10 shifts the global signal MULT to the L level. Accordingly, the accumulation of charges in the capacitive devices 23_2 to 23_0 is completed, and the holding voltages V_{C,0} to V_{C,2} remain.

The operation of Cycle (3) is performed during the period from timings t5 to t6. At timing t5, the global circuit 10 shifts and maintains the global signal SUM to the H level while maintaining the global signal PRE and the global signal MULT at the L level. Accordingly, the adder circuit 24 redistributes the charges accumulated in the n capacitive devices 23_(n−1) to 23_0 depending on their respective capacitance ratios. The capacitance values of the n capacitive devices 23_(n−1) to 23_0 are equal, so the charges of the n capacitive devices 23_(n−1) to 23_0 are redistributed so that the accumulated voltages are averaged. Accordingly, the adder circuit 24 generates the output voltage V_{Y} and supplies the output node 20b. The output voltage V₁ corresponds to a voltage obtained by averaging a plurality of voltages V_{C,0} to V_{C,1} as a result obtained by the plurality times of multiplication. The output voltage V₁ can be converted into an addition result by multiplying the number of capacitive devices 23 (i.e., n). The output voltage V_{Y} is given by Formula 3.

$$[ Mathematical 3 ]$$

$${V}_{Y} = \frac{{V}_{X}}{n} {\sum }_{i = 0}^{n - 1} \frac{{b}_{i}}{{2}^{n - i - 1}} = \frac{XW}{n} ; where W = {\sum }_{i = 0}^{n - 1} \frac{{b}_{i}}{{2}^{n - i - 1}} \qquad Formula 3$$

In one example, in the case where n=3 and the weight W=(b₂, b₁, b₀)=(1, 1, 1) , the adder circuit 24 redistributes the charges accumulated in the three capacitive devices 23_2 to 23_0 and generates the output voltage V_{Y}=(V_{C,0}+V_{C,1}+V_{C,2})/3={V_{X}+(V_{X}/2)+(Vₓ/2²)}/3.

As illustrated in FIG. 1, the semiconductor integrated circuit 1 outputs the output voltage V_{Y} to the output circuit 3. The output circuit 3 converts the output voltage V_{Y} into the output data Dₒᵤₜ. In one example, if the output voltage V_{Y} is multiplied by the number of capacitive devices 23 (e.g., three) before or after the output voltage V is A/D-converted in the output circuit 3, the output of the output circuit 3 is the addition result. However, it is often sufficient to obtain an output proportional to the addition result, so it is not always necessary to multiply the number of the capacitive devices 23. The output circuit 3 outputs the generated output data Dₒᵤₜ.

As described above, according to the first embodiment, the semiconductor integrated circuit 1 multiplies the plurality of input voltages having a positive signal amplitude by the weight of multiple bits representing a positive integer and accumulates charges corresponding to the plurality of multiplication results in parallel in the plurality of capacitive devices. Then, the charges of the plurality of capacitive devices are collectively redistributed in such a way that the accumulated voltages are averaged, and the averaged accumulated voltage is generated as an output voltage corresponding to the addition result. Thus, it is possible to obtain the addition result without performing the bit shift and to obtain fixed processing time of parallel operation regardless of the bit precision of any one of input or weight.

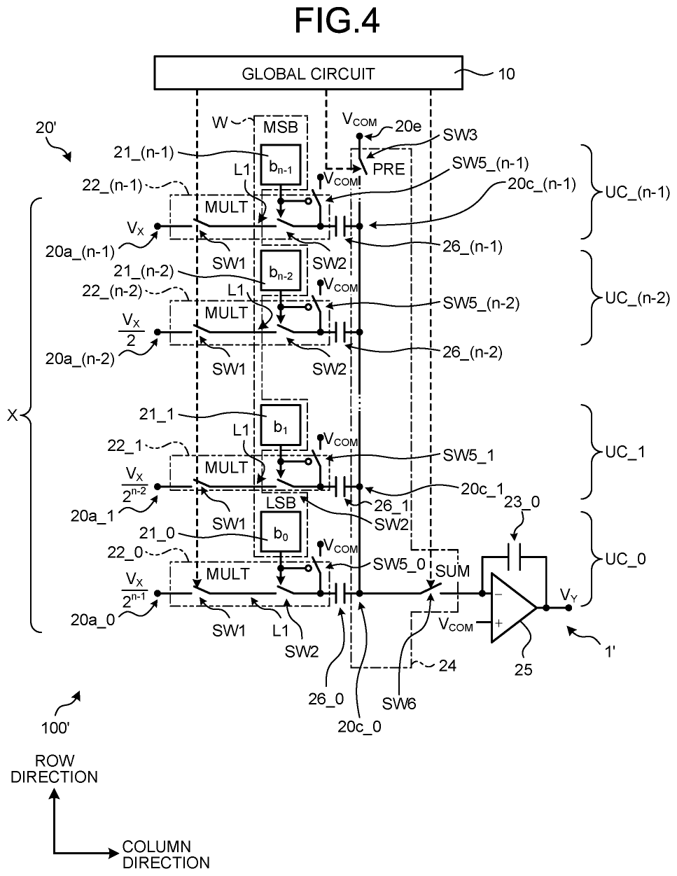

Moreover, as illustrated in FIG. 4, in a semiconductor integrated circuit 1′ of an arithmetic logic operation system 100′ according to a modification of the first embodiment, an arithmetic logic operation circuit 20′ can be configured to generate an output voltage in such a way that the adder circuit 24 adds a charge. FIG. 4 is a circuit diagram illustrating a configuration of the semiconductor integrated circuit according to the modification of the first embodiment. In one example, (n−1) capacitive devices 23_(n−1) to 23_1 and n switches SW4_(n−1) to SW4_0 in the configuration illustrated in FIG. 2 are omitted in the arithmetic logic operation circuit 20′ illustrated in FIG. 4. In this configuration, capacitive devices 26_(n−1) to 26_0 are respectively placed in series with switch SW2 and node 20c. Also, the switches SW5_(n−1) to SW5_0 are respectively connected in parallel with switch SW2 to the capacitive devices 26_(n−1) to 26_0. Each of the switch SW5 has a first end connected to the common voltage VCOM, a second end connected to a node between the switch SW2 and the capacitive device 26, and a control terminal provided with a level logically inverted with respect to the output of the storage devices 21. The operation of the arithmetic logic operation circuit 20′ is basically similar to that of the arithmetic logic operation circuit 20 but differs in the following points. At timings t3 to t6 illustrated in FIG. 3D, it is shown as a waveform of a charge integrating circuit 25, which can be composed of a capacitive feedback operational amplifier illustrated in FIG. 4, and the amplitude thereof provides, depending on (e.g., proportional to) the capacitive ratio between the capacitive device 26 and a feedback capacitance 23_0, the total amplitude shown in timings t3 to t6. Here, the capacitive device 23_0 is provided in the feedback line of the charge integrating circuit 25. In other words, the arithmetic logic operation circuit 20′ adds the charges collectively by accumulating a plurality of multiplication results in parallel in one capacitive device in the charge integrating circuit 25 and outputs a voltage corresponding to (e.g., proportional to) the added charges as an output voltage. The adder circuit 24 has a switch SW6 between the node 20c and the charge integrating circuit 25. The charge integrating circuit 25 has an inverted input node connected to the switch SW6, a non-inverted input node provided with the common voltage VCOM, and an output node for outputting the output voltage V_{Y}, where the inverted input node and the output node are feedback-connected via the capacitive device 23_0. Such a configuration makes it possible to obtain the addition result without performing the bit shift, fixing the processing time of the parallel operation regardless of the bit precision of either the input or the weight.

### Second Embodiment

An arithmetic logic operation system 200 according to a second embodiment is now described. The configurations different from the first embodiment are hereinafter mainly described.

Although the first embodiment illustrates the configuration of the semiconductor integrated circuit in the case where multiple bits of the weight represent a positive integer, the second embodiment illustrates a semiconductor integrated circuit of a case where multiple bits of the weight represent a positive or negative integer.

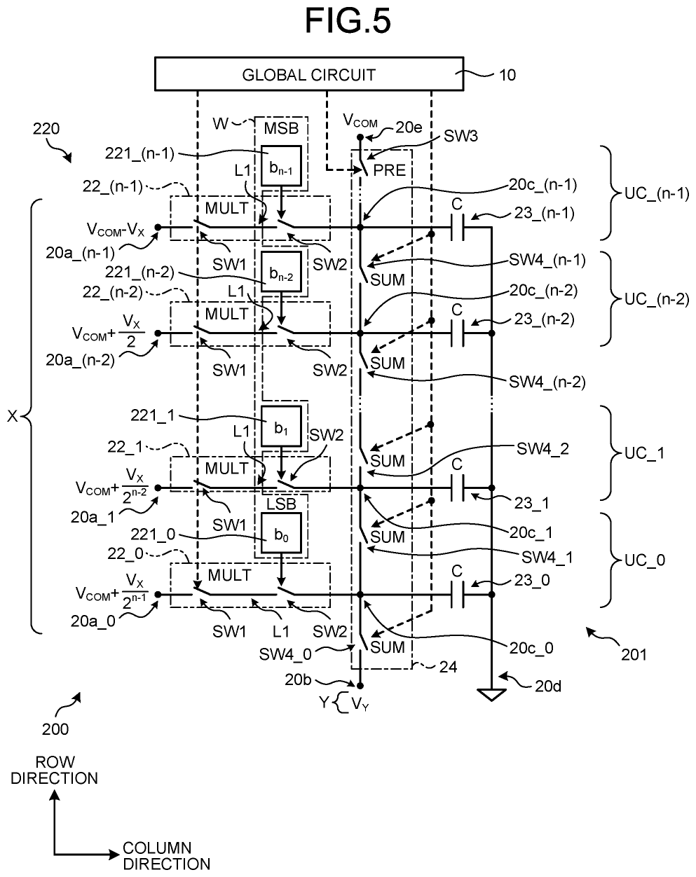

The arithmetic logic operation system 200 has a semiconductor integrated circuit 201 instead of the semiconductor integrated circuit 1 (see FIG. 2). The semiconductor integrated circuit 201 can be configured as illustrated in FIG. 5. The semiconductor integrated circuit 201 has an arithmetic logic operation circuit 220 instead of the arithmetic logic operation circuit 20 (see FIG. 2). The arithmetic logic operation circuit 220 has n storage devices 221_(n−1) to 221_0 instead of the n storage devices 21_(n−1) to 21_0 (see FIG. 2). The n storage devices 221_(n−1) to 221_0 have multiple bits of the weight W to be stored, which are different from the first embodiment. In other words, the n-bit patterns “bₙ₋₁, bₙ₋₂, . . . , b₁, b₀” of the weight W represent a positive or negative integer in two's complement representation. The bit bₙ₋₁, which is the MSB, is a sign bit, and it indicates that the multi-bit pattern is a positive integer when the value is 0 and the multi-bit pattern is a negative integer when the value is 1. In the case where the n-bit pattern “bₙ₋₁, bₙ₋₂, . . . , b₁, b₀” represents a negative integer, the n-bit pattern is a bit pattern in which each bit of the bit pattern representing the absolute value is inverted and 1 is added to the inverted bit pattern.

The n input voltages being input from the input circuit 2 to the semiconductor integrated circuit 201 respectively correspond to n bits bₙ₋₁, bₙ₋₂, . . . , b₁, b₀ of the weight W. Each input voltage has a positive or negative signal amplitude corresponding to the position of the individually corresponding bit when the common voltage V_{COM} is set to 0 V. The input signal received from the input circuit 2 by the input node 20a_(n−1) in the row line (n−1) is given as Formula 4 below. The input signal received from the input circuit 2 by the input node 20a_i in the row line i is given as Formula 5 below. In Formula 5, i=(n−2) to 0.

$$[ Mathematical 4 ]$$

$$row line u - 1 : {V}_{X , n - i} = {V}_{COM} - {V}_{X} \qquad Formula 4$$

$$other row line is {V}_{x , i} = {V}_{COM} + \frac{{V}_{X}}{{2}^{n - i - 1}} \qquad Formula 5$$

The arithmetic logic operation circuit 220 performs arithmetic logic operation for a scalar product Y=X·W of an input vector X=(V_{COM}−V_{X}, V_{COM}+V_{X}/2, . . . , V_{COM}+V_{COM} +V_{X}/2n⁻¹) and a weight vector W=(bₙ₋₁, bₙ₋₂, . . . , b₁, b₀) , but the n-bit pattern “bₙ₋₁, bₙ₋₂, . . . , b₁, b₀” of the weight W can be represented as a negative integer.

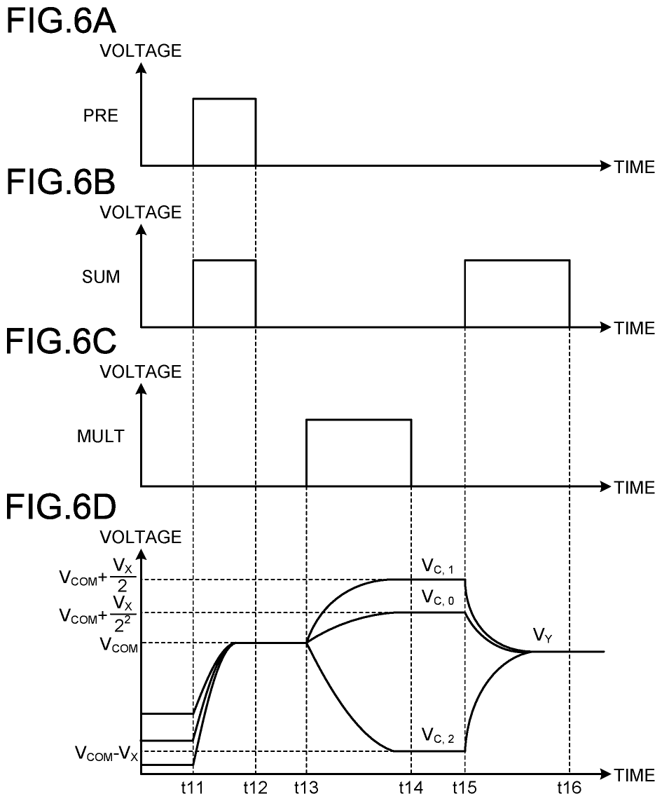

For example, in the case where the parameter V_{X} has a positive value and the n-bit patterns of the weight W represent a negative integer, the semiconductor integrated circuit 201 can operate as illustrated in FIGS. 6A to 6D. FIGS. 6A to 6D are waveform diagrams illustrating the operation of the semiconductor integrated circuit 201. FIG. 6A illustrates the temporal transition of levels of the global signal PRE. FIG. 6B illustrates the temporal transition of levels of the global signal SUM. FIG. 6C illustrates the temporal transition of levels of the global signal MULT. FIG. 6D illustrates the temporal variation of the holding voltage of each capacitive device 23.

Immediately before timing tll, the global circuit 10 maintains the global signals PRE, SUM, and MULT at the L level. The semiconductor integrated circuit 201 sets the potential of the common voltage V_{COM} to an intermediate potential between the ground potential and the power supply potential of the semiconductor integrated circuit 201. In one example, the semiconductor integrated circuit 201 sets the common voltage to V_{COM} =Vdd/2. Here, Vdd is the power supply potential. The common voltage V_{COM} has a potential of Vdd/2, but has 0 V (reference value) concerning the signal amplitude of the input vector X. The input voltage has a positive signal amplitude Vin−Vdd/2 if its potential Vin is higher than Vdd/2, and has a negative signal amplitude Vin−Vdd/2 if the potential Vin is lower than Vdd/2. It should be noted that |Vin| should always be smaller than Vdd/2.

In one example, in the case where n=3 and the weight W=(b₂, b₁, b₀)=(1, 1, 1) , the weight W represents a negative integer corresponding to “−1” in decimal.

During the period from timings t11 to t12, an operation different from Cycle (1) of the first embodiment is performed as described in the following points depending on the common voltage V_{COM} being Vdd/2. At timing t11, the global circuit 10 shifts and maintains individually the global signals PRE and SUM to the H level while maintaining the global signal MULT to the L level. Accordingly, the holding voltages V_{C, 0} to V_{C,2} of the capacitive devices 23_2 to 23_0 are reset to V_{COM}=Vdd/2 (=signal amplitude of 0 V)

During the period from timings t13 to t14, an operation different from Cycle (2) of the first embodiment is performed as described in the following points depending on the common voltage V_{COM} being Vdd/2. At timing t13, the global circuit 10 shifts and maintains the global signal MULT to the H level while maintaining the global signal PRE and the global signal SUM at the L level. Accordingly, in the case where the bit value bᵢ=1 of the weight W, the holding voltage of the capacitive device 23_i gradually varies from V_{COM} =Vdd/2 to V_{X,i}. In the case where the parameter V_{X} has a positive value, the input voltage V_{X,n-1} corresponding to bₙ₋₁ of the MSB of the weight W has a negative signal amplitude, and the holding voltage of the capacitive device 23_(n−1) decreases from V_{COM} to V_{X,n-1} gradually. In the case where the other input voltage V_{X,i} (where i=(n−2) to 0) has a positive signal amplitude, the holding voltage of the capacitive device 23_i gradually increases from V_{COM} to V_{X,i}. In the case where the bit value bᵢ=0 of the weight W, the holding voltage of the capacitive device 23_i remains V_{COM}. In other words, the charge accumulated in the capacitive device 23_(n−1) in the row line (n−1) is given as in Formula 6 below, and the charge accumulated in the capacitive device 23_i in the row line i is given as in Formula 7 below. In Formula 7, i=(n−2) to 0.

$$[ Mathematical 5 ]$$

$${Q}_{n - 1} = C ( {V}_{COM} - {b}_{n - 1} {V}_{X} ) \qquad Formula 6$$

$${Q}_{i} = C ( {V}_{COM} + \frac{{V}_{X} {b}_{i}}{{2}^{n - i - 1}} ) ; ∀ i ∈ [ n - 2 , 0 ] \qquad Formula 7$$

In one example, in the case where n=3 and the weight W=(b₂, b₁, b₀)=(1, 1, 1) , the input signal V_{COM}−V_{X} is applied to the first end of the capacitive device 23_2 depending on the bit value b₂=1 of the weight W in the row line 2, and the holding voltage V_{C,2} of the capacitive device 23_2 gradually decreases from V_{COM} to V_{COM}−V_{X}. Accordingly, the charge Q₂=C _{X} (V_{COM} V_{X}) is accumulated in the capacitive device 23_2. In the row line 1, the input signal V_{COM} +V_{X}/2 is applied to the first end of the capacitive device 23_1 depending on the bit value b₁=1 of the weight W, and the holding voltage V_{C,1} of the capacitive device 23_1 is gradually increased from V_{COM} to V_{COM}+V_{X}/2. Accordingly, the charge Q₁=C×(V_{COM}+V_{X}/2) is accumulated in the capacitive device 23_1. In the row line 0, the input signal V_{COM}+V_{X}/2² is applied to the first end of the capacitive device 23_0 depending on the bit value b₀=1 of the weight W, and the holding voltage V_{C,0} of the capacitive device 23_0 is gradually increased from V_{COM} to V_{COM}+V_{X}/2². Accordingly, the charge Q₁=C×(V_{COM}+V_{X}/2²) is accumulated in the capacitive device 23_0.

During the period from timings t15 to t16, an operation similar to Cycle (3) of the first embodiment is performed. The adder circuit 24 collectively redistributes the charges accumulated in the n capacitive devices 23_(n−1) to 23_0 in such a way that the accumulated voltages are averaged, generates the output voltage V_{Y} as given in Formula 8 and supplies the output node 20b with the generated voltage.

$$[ Mathematical 6 ]$$

$${V}_{Y} = {V}_{COM} + \frac{{V}_{X}}{n} ( - {b}_{n - 1} + {\sum }_{i = 0}^{n - 2} \frac{{b}_{i}}{{2}^{n - i - 1}} ) \qquad Formula 8$$

Moreover, the parameter V, that defines each element of the input vector X can have values ranging from −V_{COM} to +V_{COM}. The parameter V_{X} can also have a negative value.

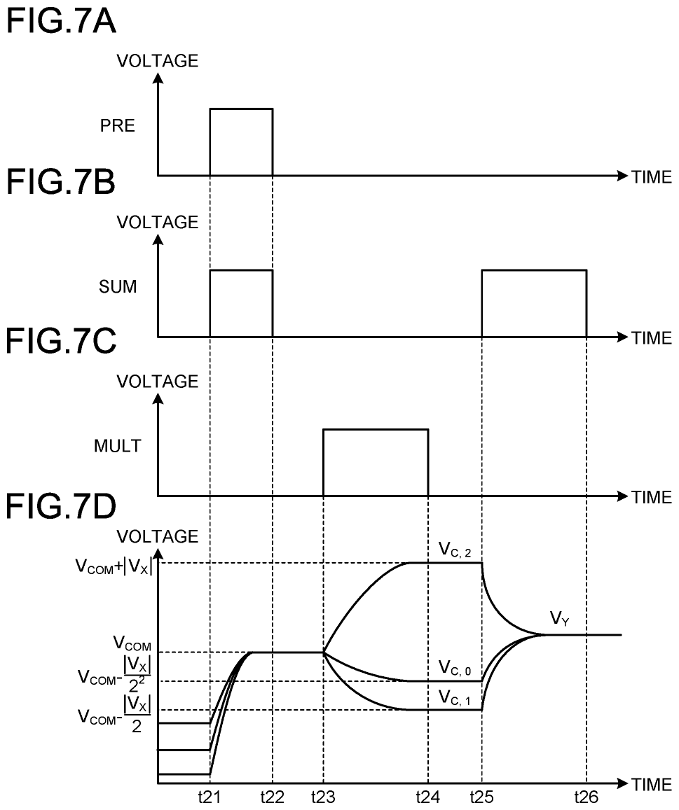

For example, in the case where the parameter V_{X} has a negative value and the multi-bit pattern of the weight W represent a negative integer, the semiconductor integrated circuit 201 operates as illustrated in FIGS. 7A to 7D differently from FIGS. 6A to 6D on the following points. FIGS. 7A to 7D are waveform diagrams illustrating another operation of the semiconductor integrated circuit 201. FIG. 7A illustrates the temporal transition of levels of the global signal PRE. FIG. 7B illustrates the temporal transition of levels of the global signal SUM. FIG. 7C illustrates the temporal transition of levels of the global signal MULT. FIG. 7D illustrates the temporal variation of the holding voltage of each capacitive device 23.

As illustrated in FIG. 7D, the waveforms of the holding voltages V_{C,i} of each capacitive device 23 during the period of timings t23 to t26 are obtained by shifting line-symmetrically the waveforms of the holding voltages V_{C,i} (see FIG. 6D) at timings t13 to t16 with the line indicating the common voltage V_{COM} as the axis of symmetry.

During the period from timings t23 to t24, an operation different from Cycle (2) of the first embodiment is performed as described in the following points depending on the common voltage V_{COM} being Vdd/2. At timing t23, the global circuit 10 shifts and maintains the global signal MULT to the H level while maintaining the global signal PRE and the global signal SUM at the L level. Accordingly, in the case where the bit value bᵢ=1 of the weight W, the holding voltage V_{C,i} of the capacitive device 23_i gradually varies from V_{COM} to V_{X,i}. In the case where the parameter V_{X} has a negative value, V_{X}=−|V_{X}|. The input voltage V_{X,n-1} corresponding to bₙ₋₁ of the MSB of the weight W has a positive signal amplitude, and the holding voltage of the capacitive device 23_(n−1) increases from V_{COM} to V_{X,n-1} gradually. The other input voltage V_{X,i} (where i=(n-2) to 0) has a negative signal amplitude, and the holding voltage V_{C,i} of the capacitive device 23_i gradually decreases from V_{COM} to V_{X,i}. In the case where the bit value bᵢ=0 of the weight W, the holding voltage of the capacitive device 23_i remains 0 V.

In one example, in the case where n=3 and the weight W=(b₂, b₁, b₀)=(1, 1, 1) , the input signal V_{COM}−V_{X} is transferred to the first end of the capacitive device 23_2 depending on the bit value b₂=1 of the weight W in the row line 2, and the holding voltage V_{C,2} of the capacitive device 23_2 gradually increases from V_{COM} to V_{COM}−V_{X}=V_{COM}+|V_{X}|. Accordingly, the charge Q₂=C×(V_{COM}+|V_{X}|) is accumulated in the capacitive device 23_2. In the row line 1, the input signal V_{COM}+V_{X}/2 is transferred to the first end of the capacitive device 23_1 depending on the bit value b₁=1 of the weight W, and the holding voltage V_{C,1} of the capacitive device 23_1 is gradually decreased from V_{COM} to V_{COM}+V_{X}/2=V_{COM} 1V_{X}1/2. Accordingly, the charge Q₁=C×(V_{COM}−|V_{X}|/2) is accumulated in the capacitive device 23_1. In the row line 0, the input signal V_{COM}+V_{X}/2² is transferred to the first end of the capacitive device 23_0 depending on the bit value b₀=1 of the weight W, and the holding voltage V_{C,0} of the capacitive device 23_0 is gradually decreased from V_{COM} to V_{COM}+V_{X}/2²=V_{COM}−|V_{X}|/2². Accordingly, the charge Q₁=C×(V_{COM}−|V_{X}|/2²) is accumulated in the capacitive device 23_0.

During the period from timings t25 to t26, an operation similar to Cycle (3) of the first embodiment is performed. The adder circuit 24 collectively redistributes the charges accumulated in the n capacitive devices 23 (n−1) to 23_0 in such a way that the accumulated voltages are averaged, generates the output voltage V_{Y} as in Formula 8 and supplies the output node 20b with the generated voltage in a similar manner as the operation in FIGS. 6A to 6D.

As described above, according to the second embodiment, the semiconductor integrated circuit 201 multiplies a plurality of input voltages having a positive or negative signal amplitude by a multiple bits weight representing a positive or negative integer in two's complement representation. The semiconductor integrated circuit 201 redistributes the charges corresponding to the plurality of multiplication results to generate an output voltage corresponding to the addition result. This also makes it possible to obtain the addition result without performing the bit shift and to improve the efficiency of parallel operation regardless of the bit precision of any one of input or weight, obtaining fixed processing time of parallel operation.

### Third Embodiment

An arithmetic logic operation system 300 according to a third embodiment is now described. The configurations different from the first embodiment and the second embodiment are hereinafter mainly described.

The first embodiment illustrates the configuration for setting a fixed time in the case of performing the parallel operation for each bit when the multi-bit multiplication is divided for each bit of the weight. However, the third embodiment extends the configuration of the first embodiment to a configuration for achieving the fixed time for the parallel operation of vectors and matrices.

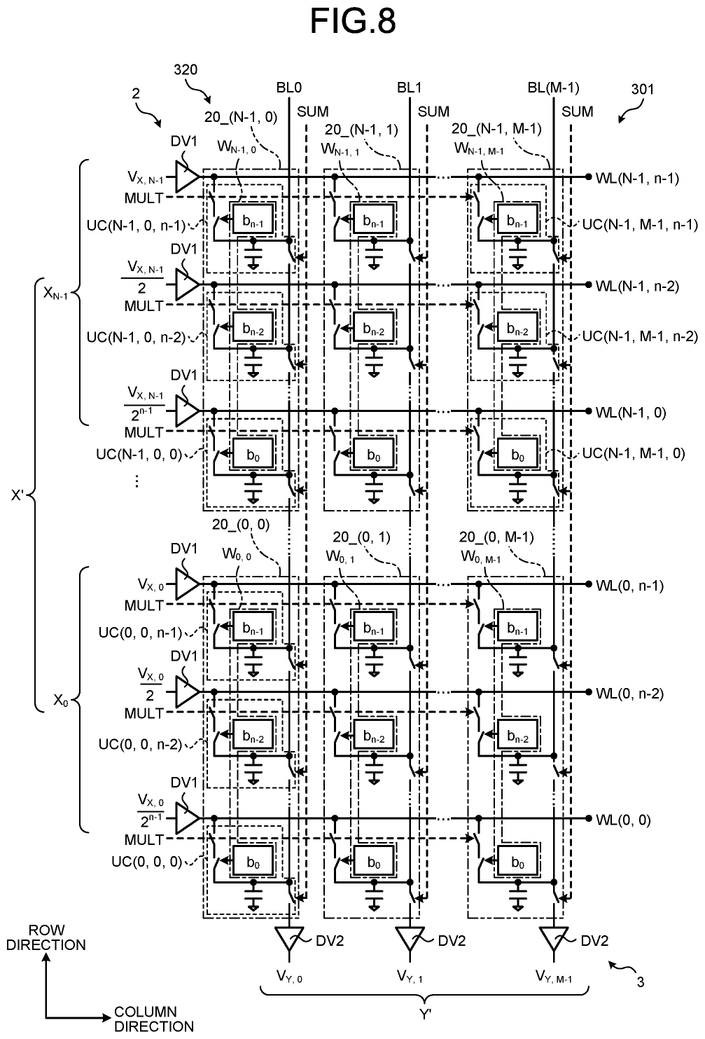

The arithmetic logic operation system 300 has a semiconductor integrated circuit 301 instead of the semiconductor integrated circuit 1. The semiconductor integrated circuit 301 can be configured as illustrated in FIG. 8. The semiconductor integrated circuit 301 has an arithmetic logic operation circuit 320 instead of the arithmetic logic operation circuit 20 (see FIG. 2). In the arithmetic logic operation circuit 320, the arithmetic logic operation circuit 20 is extended to N rows×M columns and is arranged as a plurality of arithmetic logic operation circuits 20_(N-1, M-1) to 20_(0, 0), where N and M are optional integers of 2 or more. Each arithmetic logic operation circuit 320 has a configuration similar to the arithmetic logic operation circuit 20 of the first embodiment, although the circuit notation is different.

The arithmetic logic operation circuit 320 further includes a plurality of word lines WL(N-1, n-1) to WL(0, 0) and a plurality of bit lines BL0 to BL(n−1). A plurality of unit cells UC(N-1, M-1, n-1) to UC(0, 0, 0) is arranged at positions where the plurality of word lines WL and the plurality of bit lines BL intersect. The word lines WL extend in the column direction and are arranged in the row direction. The bit lines BL extend in the row direction and are arranged in the column direction. The unit cells UC are similar to the unit cell UC of the first embodiment.

Moreover, the arithmetic logic operation circuit 20 is expanded to N rows x M columns, accordingly a driver DV1 as a part of the input circuit 2 (see FIG. 1) can be connected to each input node, and a driver DV2 as a part of the output circuit 3 (see FIG. 1) can be connected to each output node. Thus, it is possible to improve the drive capacity upon supplying the arithmetic logic operation circuit 20 in each row with the input voltage from the input node, improving the drive capacity upon supplying the output node with the output voltage from the arithmetic logic operation circuit 20 in each column.

The arithmetic logic operation circuit 320 performs the arithmetic logic operation for a scalar product of an input vector X′ expressed in Formula 9 and a weight matrix W′ expressed in Formula 10. A plurality of output voltages V_{Y,j} (j=M-1 to 0) included in the output vector Y′ =X′W′ expressed in Formula 11 as the arithmetic logic operation result is input to the output circuit 3.

$$[ Mathematical 7 ]$$

$${X}^{′} = ( \begin{matrix}{X}_{N - 1} \\ ⋮ \\ {X}_{0}\end{matrix} ) \qquad Formula 9$$

$${W}^{′} = ( \begin{matrix}{W}_{N - 1 , 0} & {W}_{N - 1 , 1} & … & {W}_{N - 1 , M - 1} \\ ⋮ & ⋮ & & ⋮ \\ {W}_{0 , 0} & {W}_{0 , 1} & … & {W}_{0 , M - 1}\end{matrix} ) \qquad Formula 10$$

$${Y}^{′} = ( \begin{matrix}{V}_{Y , 0} & {V}_{Y , 1} & … & {V}_{Y , M - 1}\end{matrix} ) \qquad Formula 11$$

In one example, in the case where the bit pattern of the weight W represents a positive integer, each element vector Xᵢ (i =N-1 to 0) included in the input vector X′ is similar to the input vector X in the first embodiment and includes n input voltages V_{X,i}, V_{X,i}/2, . . . , V_{X,i}/2ⁿ⁻², V_{X,i}/2ⁿ⁻¹. The input vector X′ includes N×n input voltages, each of which has a positive signal amplitude. Each element vector W_{i,j} (i=N-1 to 0, j=M-1 to 0) included in the weight matrix W′ is similar to the weight vector W in the first embodiment and includes n bits bₙ₋₁, bₙ₋₂, . . . , b₁, b₀. The point that n bits bₙ₋₁, bₙ₋₂, . . . , b₁, b₀ are stored in the n storage devices 21_(n−1) to 21_0 (see FIG. 2) is also similar to that of the first embodiment. The n-bit pattern included in each element vector W_{i,j} represents a positive integer. The weight matrix W′ includes N×n×M bits. The output voltage V_{Y} (j=M-1 to 0) included in the output vector Y′ is similar to the output voltage V_{Y} in the first embodiment and includes M output voltages.

In other words, in the arithmetic logic operation circuit 20 of each column, the multiplication circuit 22 (see FIG. 2) multiplies n input voltages by n bits to generate a plurality of multiplication results, and n capacitive devices 23 (see FIG. 2) accumulates charges corresponding to a plurality of multiplication results. Then, the adder circuit 24 of the arithmetic logic operation circuit 20 in each column collectively redistributes the charges accumulated in the n capacitive devices 23 in such a way that the accumulated voltages are averaged. The adder circuit 24 generates the output voltage V_{Y} corresponding to the addition result obtained by adding a plurality of multiplication results and outputs the output voltage V_{Y} to the output node for each column. The output voltage V_{Y,i} (j=N−1 to 0) in each column is given as Formula 12.

$$[ Mathematical 8 ]$$

$${V}_{Y , j} = \frac{1}{N} {\sum }_{r = 0}^{N - 1} \frac{{V}_{x , r} {W}_{r , j}}{n} \qquad Formula 12$$

As described above, according to the third embodiment, for the parallel operation of vectors and matrices, a plurality of input voltages having a positive signal amplitude is multiplied by a multiple bits weight representing a positive integer, and the charges corresponding to the plurality of multiplication results are redistributed for each column to generate a plurality of output voltages corresponding to the addition result of a plurality of columns. This also makes it possible to obtain the addition result without performing the bit shift and to obtain fixed processing time of parallel operation regardless of the bit precision of any one of input or weight.

Moreover, although not illustrated, in the arithmetic logic operation circuit 320, the arithmetic logic operation circuit 220 according to the second embodiment is expanded to N row×M columns and can be arranged as a plurality of arithmetic logic operation circuits 220 (N−1, M−1) to 220 (0, 0). Each arithmetic logic operation circuit 220 is basically similar to the arithmetic logic operation circuit 220 of the second embodiment. In this case, the input vector X′ includes N×n input voltages, each with a positive or negative signal amplitude. In addition, the n-bit pattern included in each element vector W_{i,j} represents a positive or negative integer in two's complement representation.

That is, for the parallel operation of vectors and matrices, a plurality of input voltages having a positive or negative signal amplitude is multiplied by a multiple bits weight representing a positive or negative integer in two's complement representation, and the charges corresponding to the plurality of multiplication results are redistributed for each column to generate a plurality of output voltages corresponding to the addition result of a plurality of columns. This also makes it possible to obtain the addition result without performing the bit shift and to obtain fixed processing time of parallel operation regardless of the bit precision of any one of input or weight.

### Fourth Embodiment

An arithmetic logic operation system 100 according to a fourth embodiment is now described. The configurations different from the first embodiment to the third embodiment are hereinafter mainly described.

Although the first to third embodiments do not describe the specific configuration of the unit cell UC, the fourth embodiment exemplifies the specific configuration of the unit cell UC.

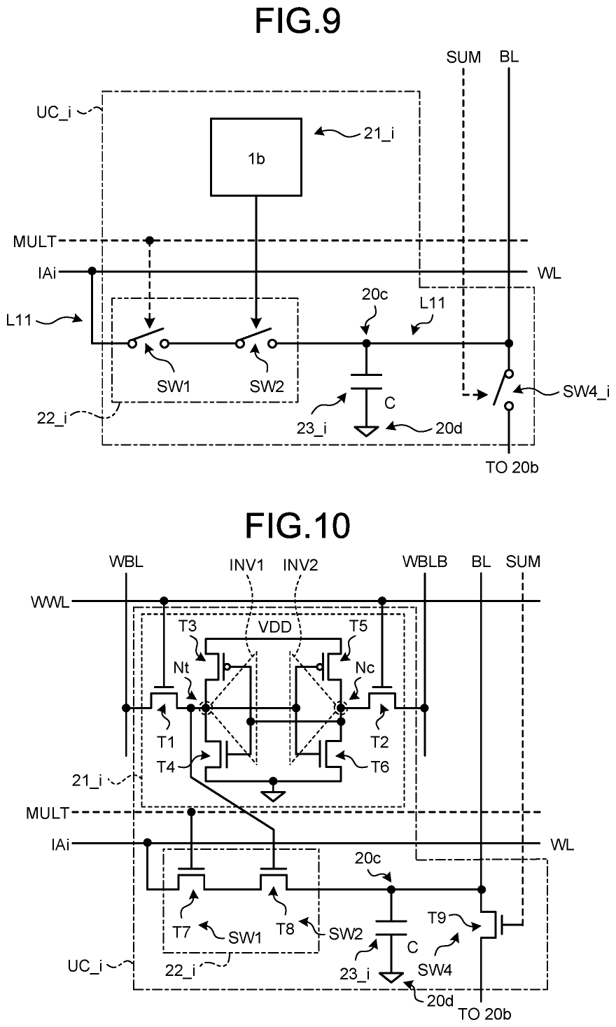

The unit cell UC is arranged at a position where the word line WL and the bit line BL intersect, as illustrated in FIG. 9. FIG. 9 is a diagram illustrating the schematic configuration of the unit cell UC and illustrates the schematic configuration of the unit cell U_ i in the row line i (where i=n-1 to 0).

A line L11 is arranged at a position where the word line WL and the bit line BL intersect. The line L11 has a first end connected to the word line WL and a second end connected to the bit line BL. The multiplication circuit 22 i in the unit cell UC_i is inserted into the line L11. The series connection of the switch SW1 and the switch SW2 in the multiplication circuit 22_i is inserted into the line L11. The capacitive device 23_i in the unit cell UC_i has a first end connected to the intermediate node 20c on the line L11 and a second end connected to the reference node 20d. The reference node 20d is supplied with a reference voltage (e.g., a ground voltage). The first end of the capacitive device 23_i is connected to the bit line BL via the intermediate node 20c. On the bit line BL, a switch SW4_i is electrically connected between the intermediate node 20c and the output node 20d.

The switch SW1 is controlled to be ON or OFF depending on the global signal MULT from the global circuit 10. The switch SW4_i is controlled to be ON or OFF depending on the global signal SUM from the global circuit 10.

The storage device 21_i in the unit cell UC_i has an output node connected to the control terminal of the switch SW2. The storage device 21_i stores one bit of the weight W and outputs a voltage corresponding to the value of the stored bit to the control terminal of the switch SW2. The switch SW2 remains ON or OFF depending on the voltage output from the storage device 21_i.

The storage device 21_i may be a volatile memory cell (e.g., an SRAM memory cell) or a non-volatile memory cell (e.g., a flash memory cell, a memory cell in which variable resistive devices are connected in two stages with opposite polarities, or the like). In considering the ease of programming and the characteristics of low power consumption during operation, it is desirable that the storage device 21_i is desirable to include an SRAM memory cell as illustrated in FIG. 10. FIG. 10 is a diagram illustrating a specific configuration of the unit cell UC_i, exemplifying the configuration of the unit cell UC_i in the case where the storage device 21_i includes the SRAM memory cell.

The storage device 21_i illustrated in FIG. 10 is a 6T SRAM cell having load transistors T3 and T5, drive transistors T4 and T6, and transfer transistors T1 and T2. The transfer transistors T1 and T2 can be constituted of an NMOS transistor. The load transistors T3 and T5 can be constituted of a PMOS transistor. The drive transistors T4 and T6 can be constituted of an NMOS transistor. The load transistor T3 and the drive transistor T4 form an inverter INV1, and the load transistor T5 and the drive transistor T6 form an inverter INV2. The output terminal of the inverter INV1 is connected to the input terminal of the inverter INV2 via a storage node Nt, and the output terminal of the inverter INV2 is connected to the input terminal of the inverter INV1 via an inverting storage node Nc. The inverters INV1 and INV2 constitute a flip-flop. The storage node Nt constitutes the output node of the storage device 21_i and is connected to the control terminal of the switch SW2.

The transfer transistor T1 is connected between the storage node Nt of the storage device 21_i and a weighting bit line WBL. The transfer transistor T2 is connected between the flip-flop inverting storage node Nc and a weight inverting bit line WBLB. The transfer transistors T1 and T2 turn ON when their gates are supplied with an active level control signal via a weighting word line WWL from the corresponding driver.

In one example, when the transfer transistors T1 and T2 turn ON while the weighting bit line WBL remains at the H level and the weight inverting bit line WBLB remains at the L level, the H level is held in the storage node Nt and the L level is held in the inverting storage node Nc. In other words, the bit value “1” is written in the storage device 21_i. The inverter INV1 and the inverter INV2 operate in a complementary manner, the H level is held in the storage node Nt, and the L level is held in the inverting storage node Nc even after the transfer transistors T1 and T2 turn OFF. In other words, the storage device 21_i holds the bit value “1” and outputs the H level voltage corresponding to the bit value “1” to the control terminal of the switch SW2.

When the transfer transistors T1 and T2 turn ON while the weighting bit line WBL remains at the L level and the weight inverting bit line WBLB remains at the H level, the L level is held in the storage node Nt and the H level is held in the inverting storage node Nc. In other words, the bit value “0” is written in the storage device 21_i. The inverter INV1 and the inverter INV2 operate in a complementary manner, the L level is held in the storage node Nt, and the H level is held in the inverting storage node Nc even after the transfer transistors T1 and T2 turn OFF. In other words, the storage device 21_i holds the bit value “0” and outputs the L level voltage corresponding to the bit value “0” to the control terminal of the switch SW2.

In the unit cell UC_i, the switches SW1, SW2, and SW4 i can be constituted of transistors T7, 18, and T9, respectively. The transistors T7, T8, and T9 can be constituted of an NMOS transistor. The transistor T7 has a source connected to the word line WL, a drain connected to the transistor T8, and a gate that receives the global signal MULT. The transistor T8 has a source connected to the transistor T7, a drain connected to the bit line BL via the intermediate node 20c, and a gate that receives a voltage output from the storage node Nt of the storage device 21_i. The transistor T9 has a source that can be connected to the output node 20b, a drain that can be connected to the common voltage V_{COM} via the switch SW3 (see FIGS. 2 and 5), and a gate that receives the global signal SUM. The unit cell UC_i illustrated in FIG. 10 can be regarded as an SRAM cell obtained by expanding a 6T SRAM cell to a 9T1C type. The configuration of the 9T1C type unit cell UC_i will be referred to as SRAMx.

Moreover, in the case where the storage device 21_i is a volatile memory cell (SRAM memory cell), the backup power can be supplied from a power storage device (not illustrated) to the power node VDD of the storage device 21_i. Accordingly, the bit value of the weight W can be non-volatilely stored in the storage device 21_i even when the power of the semiconductor integrated circuit 1 is turned OFF. The power storage device is, for example, a secondary battery.

As described above, according to the fourth embodiment, in the unit cell UC_i, the storage device 21_i is constituted of a 6T SRAM cell, and the switches SW1, SW2, and SW4 are constituted of transistors, so it is possible to implement the unit cell UC_i in the 9T1C configuration (SRAMx).

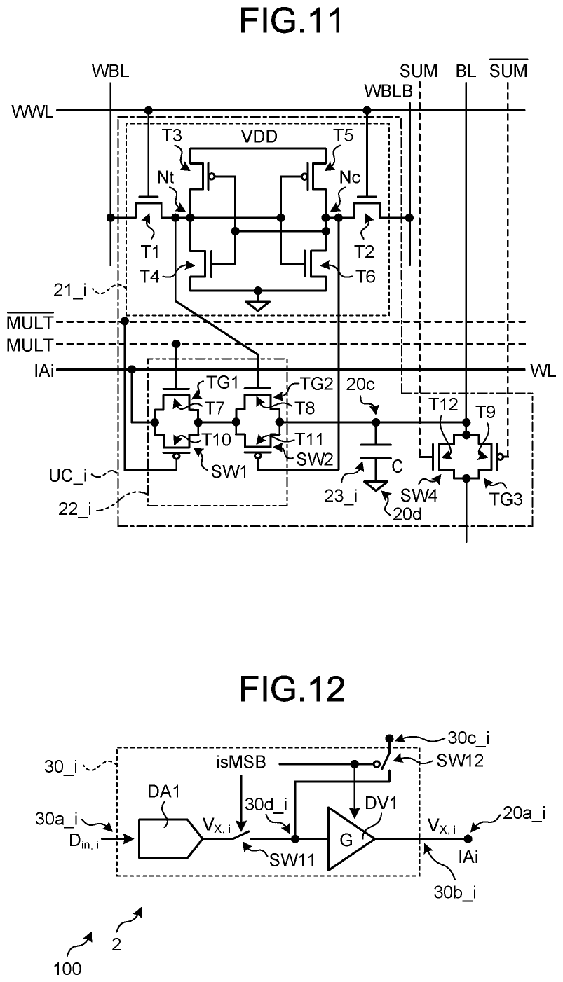

Moreover, the unit cell UC_i can be configured as illustrated in FIG. 11 instead of the configuration illustrated in FIG. 10. FIG. 11 is a diagram illustrating a specific configuration of the unit cell UC_i according to a modification of the fourth embodiment. In this case, in the unit cell UC_i, the switches SW1, SW2, and SW4_i can be constituted of transfer gates TG1, TG2, and TG3, respectively. Accordingly, the global circuit 10 further outputs global signals MULT⁻ and SUM⁻. The global signal MULT⁻ is a signal in which the global signal MULT is logically inverted. The global signal SUM⁻ is a signal in which the global signal SUM is logically inverted.

The transfer gate TG1 includes transistors T7 and T10 to which their respective sources and drains are commonly connected. The transistors T7 and T10 can be constituted of an NMOS transistor and a PMOS transistor, respectively. The transistor T10 has a source connected to the word line WL, a drain connected to the transfer gate TG2, and a gate receiving the global signal MULT⁻.

The transfer gate TG2 includes transistors T8 and T11 to which their respective sources and drains are commonly connected. The transistors T8 and T11 can be constituted of an NMOS transistor and a PMOS transistor, respectively. The transistor T11 has a source connected to the transfer gate TG1, a drain connected to the bit line BL via the intermediate node 20c, and a gate that receives a voltage output from the inverting storage node Nc of the storage device 21_i.

The transfer gate TG3 includes transistors T9 and T12 to which their respective sources and drains are commonly connected. The transistors T9 and T12 can be constituted of an NMOS transistor and a PMOS transistor, respectively. The transistor T12 has a source that can be connected to the output node 20b, a drain that can be connected to the common voltage V_{COM} via the switch SW3 (see FIGS. 2 and 5), and a gate that receives the global signal SUM⁻.

The unit cell UC_i illustrated in FIG. 11 can be regarded as an SRAM cell obtained by expanding the 6T SRAM cell to a 12T1C type. The configuration of the 12T1C unit cell UC_i illustrated in FIG. 11 is also referred to as SRAMx. That is, in the unit cell UC_i, the storage device 21_i is constituted of a 6T SRAM cell, and the switches SW1, SW2, and SW4 are constituted of 2T transfer gates, so it is possible to implement the unit cell UC_i in the 12T1C configuration (SRAMx).

### Fifth Embodiment

An arithmetic logic operation system 100 according to a fifth embodiment is now described. The configurations different from the first embodiment to the fourth embodiment are hereinafter mainly described.

Although the first embodiment does not describe in detail the configuration of the input circuit of the semiconductor integrated circuit, the fifth embodiment illustrates the specific configuration of the input circuit of the semiconductor integrated circuit.

In the arithmetic logic operation system 100 illustrated in FIG. 1, the input circuit 2 converts the input data Dᵢₙ =(dₘ₋₁, dₘ₋₂, . . . , d₁, d₀) of the digital domain into the input vector X=(V_{X}, Vₓ/2, . . . , V_{X}/2ⁿ⁻², V_{X}/2ⁿ⁻¹) of the analog domain. The input circuit 2 inputs the converted result to the arithmetic logic operation circuit 20 of the semiconductor integrated circuit 1. It is conceivable to prepare n unit configurations 30_(n−1) to 30_0 as the configuration of the input circuit 2.

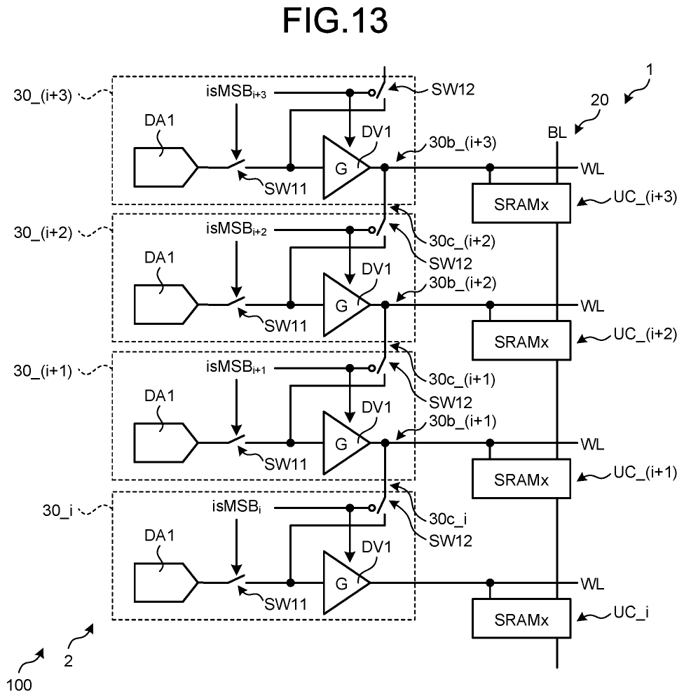

Each unit configuration 30 can be configured as illustrated in FIG. 12. FIG. 12 is a diagram illustrating the unit configuration 30 in the input circuit 2, exemplifying the unit configuration 30_i of the row line i (where i=m−1 to 0). The unit configuration 30_i includes a D/A converter DA1, a driver DV1, a switch SW11, and a switch SW12. The D/A converter DA1 is electrically connected between an input node 30a_i and the switch SW11. The switch SW11 is electrically connected between the D/A converter DA1 and an intermediate node 30d_i. The driver DV1 is electrically connected between the intermediate node 30d_i and an output node 30b_i. The switch SW12 is electrically connected between an input node 30c_i and the intermediate node 30d_i. The input node 30c_i can be connected to an output node 30b_(i+1) of the unit configuration 30_(i+1) adjacent in the row direction (e.g., one level higher) (see FIG. 13).

The D/A converter DA1 converts digital signals D_{in,i} into the analog signals V_{X,i}. A row control signal isMSB indicates whether the bit bᵢ of the weight W of the corresponding row is the MSB. The row control signal isMSB is set to the active level (e.g., 1) when the bit bᵢ of the weight W of the corresponding row is the MSB and is set to the non-active level (e.g., 0) when the bit bᵢ of the weight W of the corresponding row is not the MSB.

The switch SW11 is controlled to be ON or OFF depending on the row control signal isMSB. The switch SW11 receives the row control signal isMSB at its control terminal. The switch SW11 remains ON when its control terminal is supplied with an active level row control signal isMSB, and remains OFF when its control terminal is supplied with a non-active level row control signal isMSB. In other words, the switch SW11 remains ON when the bit ID, of the weight W of the corresponding row is the MSB, and the switch SW11 remains OFF when the bit b, of the weight W of the corresponding row is not the MSB.

The switch SW12 is controlled to be ON or OFF depending on the row control signal isMSB⁻ in which the row control signal isMSB is logically inverted. The switch SW12 receives the row control signal isMSB⁻ at its control terminal. The switch SW12 remains OFF when its control terminal is supplied with a non-active level row control signal isMSB⁻, and remains ON when its control terminal is supplied with an active level row control signal isMSB⁻. In other words, the switch SW12 remains OFF when the bit bᵢ of the weight W of the corresponding row is the MSB, and the switch SW12 remains ON when the bit bᵢ of the weight W of the corresponding row is not the MSB.

The driver DV1 has a variable gain G. The driver DV1 sets the variable gain G to G =1 when its control terminal is supplied with the active level row control signal isMSB, and sets the variable gain G to G=0.5 when its control terminal is supplied with the non-active level row control signal isMSB. When the variable gain G=1, the drive capacity of the driver DV1 corresponds to a first capacity, and when the variable gain G=0.5, the drive capacity of the driver DV1 corresponds to a second capacity. In other words, the drive capacity of the driver DV1 is controlled to be the first capacity when the bit bᵢ of the weight W in the corresponding row is the MSB. The drive capacity of the driver DV1 is controlled to be the second capacity lower than the first capacity when the bit bᵢ of the weight W in the corresponding row is not the MSB.

The input circuit 2 can be configured by connecting the n unit configurations 30_(n−1) to 30_0 in a ladder shape, as illustrated in FIG. 13. FIG. 13 is a circuit diagram illustrating the configuration of the input circuit 2, exemplifying a plurality of unit configurations (i+3) to 30 i corresponding to a plurality of optional rows (row lines (i+3) to i) in the arithmetic logic operation circuit 20.

The input node 30c_i of the unit configuration 30_i is connected to the output node 30b (i+1) of the unit configuration 30_(i+1) one level higher. An input node 30c_(i+1) of the unit configuration 30_(i+1) is connected to an output node 30b_(i+2) of a unit configuration (i+2) one level higher. An input node 30c_(i+2) of the unit configuration 30_(i+2) is connected to an output node 30b_(i+3) of a unit configuration 30_(i+3) one level higher.

The switches SW11 and SW12 of the unit configuration 30_i are controlled to be ON or OFF depending on the row control signals isMSBᵢ and isMSBᵢ⁻, respectively. The switches SW11 and SW12 of the unit configuration 30_(i+1) are controlled to be ON or OFF depending on the row control signals isMSBᵢₗₗ and isMSBᵢₗₗ⁻, respectively. The switches SW11 and SW12 of the unit configuration 30_(i+2) are controlled to be ON or OFF depending on the row control signals isMSBᵢ₊₂ and isMSBᵢ₊₂⁻, respectively. The switches SW11 and SW12 of the unit configuration 30_(i+3) are controlled to be ON or OFF depending on the row control signals isMSBᵢ₊₃ and isMSBᵢ₊₃⁻, respectively.

The input signals V_{X,i+3} to V_{X,i}, which are input to the semiconductor integrated circuit 1 from the plurality of unit configurations 30_(i+3) to 30_i, are driven with a gain of 1 or 0.5 by the driver DV1 depending on the bit precision n of the weight W. In other words, in the unit configuration 30 corresponding to the MSB row among the plurality of rows corresponding to the multiple bits n of the weight W, the variable gain G of the driver DV1 is set to G =1. In the unit configuration 30 corresponding to the other row lines, the variable gain G of the driver DV1 is set to G=0.5.

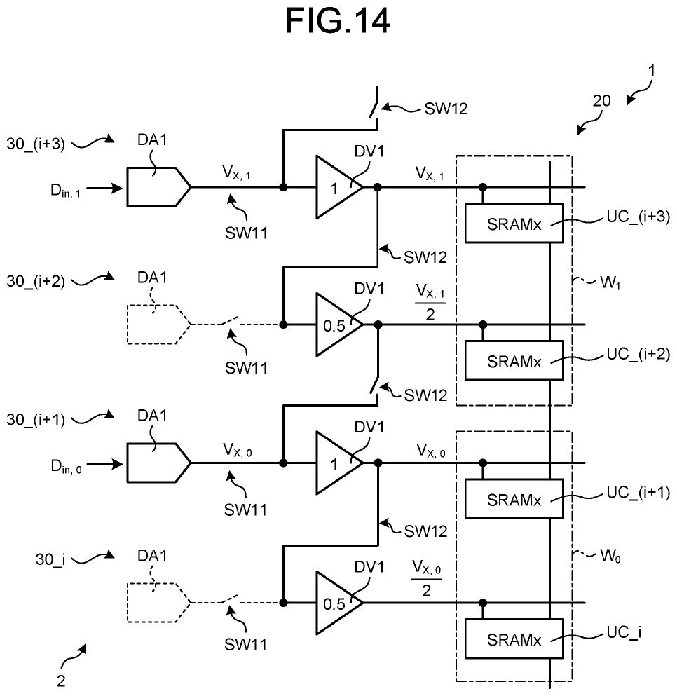

In one example, in the case of the bit precision n=2 of the weight W, the connection of the circuit illustrated in FIG. 13 is configured as illustrated in FIG. 14. FIG. 14 is a diagram illustrating a use case of the input circuit 2 (when n=2). Each unit cell UC is, for example, SRAMx as illustrated in FIG. 10 or FIG. 11.

In the example illustrated in FIG. 14, two bits b₁ and b₀ of a weight W₁ are held in two unit cells UC_(i+3) and UC_(i+2), respectively. Accordingly, the switch SW11 of the unit configuration 30_(i+3) corresponding to the MSB remains ON, and the switch SW11 of the unit configuration (i+2) corresponding to the other bit remains OFF. The switch SW12 of the unit configuration 30_(i+3) corresponding to the MSB remains OFF, and the switch SW11 of the unit configuration 30_(i+2) corresponding to the other bit remains ON. Accordingly, the D/A converter DA1 in the row line (i+2) is deactivated, and the output node of the driver DV1 in the row line (i+3) is connected to the input node of the driver DV1 in the row line (i+2). The variable gains G of the driver DV1 in the row line (i+3) and the driver DV1 in the row line (i+2) are set to 1 and 0.5, respectively.

Such a configuration enables an analog signal V_{X,1}, which is output from the D/A converter DA1 in the row line (i+3) depending on the input data D_{in, 1}, to be transmitted as the input voltage V_{X},₁ to unit cell UC_(i+3) of the arithmetic logic operation circuit 20 via the driver DV1 in the row line (i+3). In addition, the analog signal V_{X,1} is transmitted to the unit cell UC_(i+2) of the arithmetic logic operation circuit 20 as the input voltage V_{X,1}/2 via the driver DV1 in the row line (i+3) and the driver DV1 in the row line (i+2).

Further, two bits b₁ and b₀ of a weight W₀ are held in two unit cells UC_(i+1) and UC_i. Accordingly, the switch SW11 of the unit configuration 30_(1+1) corresponding to the MSB remains ON, and the switch SW11 of the unit configuration 30_i corresponding to the other bit remains OFF. The switch SW12 of the unit configuration 30_(i+1) corresponding to the MSB remains OFF, and the switch SW11 of the unit configuration 30_i corresponding to the other bit remains ON. Accordingly, the D/A converter DA1 in the row line i is deactivated, and the output node of the driver DV1 in the row line (i+1) is connected to the input node of the driver DV1 in the row line i. The variable gains G of the driver DV1 in the row line (i+1) and the driver DV1 in the row line i are set to 1 and 0.5, respectively.

Such a configuration enables an analog signal V_{X,0}, which is output from the D/A converter DA1 in the row line (i+l) depending on the input data D_{in,0}, to be transmitted as the input voltage V_{X,0} to unit cell UC_(i+1) of the arithmetic logic operation circuit 20 via the driver DV1 in the row line (i+1). In addition, the analog signal V_{X,0} is transmitted to the unit cell UC_i of the arithmetic logic operation circuit 20 as the input voltage V_{X,0}/2 via the driver DV1 in the row line (i+1) and the driver DV1 in the row line i.

The connection configuration illustrated in FIG. 14 makes it possible to reduce the number of D/A converters DA1 operating in the input circuit 2 to one-half of the number of rows, decreasing the power consumption of the arithmetic logic operation system 100 including the input circuit 2.

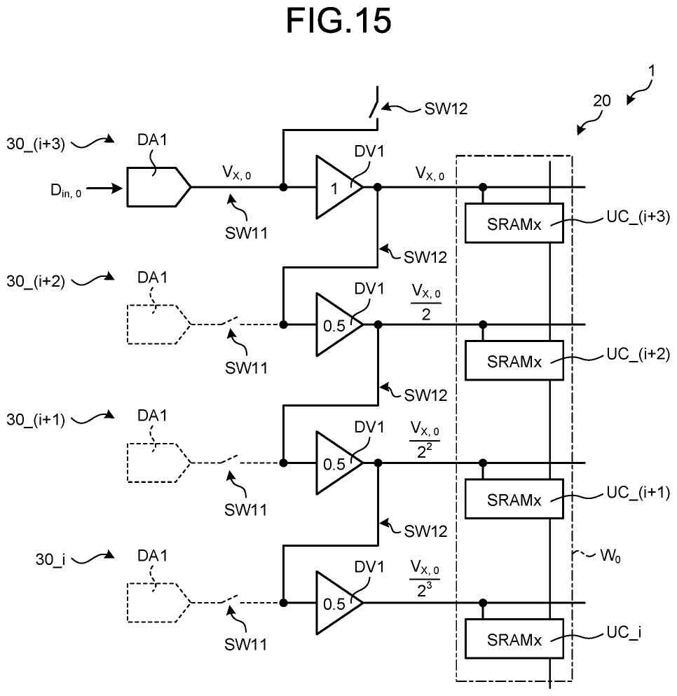

In one example, in the case of the bit precision n=4 of the weight W, the connection of the circuit illustrated in FIG. 13 is configured as illustrated in FIG. 15. FIG. 15 is a diagram illustrating a use case of the input circuit 2 (when n=4). Each unit cell UC is, for example, SRAMx as illustrated in FIG. 10 or FIG. 11.

In the example illustrated in FIG. 15, four bits b₃, b₂, b₁, and b₀ of a weight W₀ are held in four unit cells UC_(i+3), UC_(i+2), UC_(i+1), and UC_i respectively. Accordingly, the switch SW11 of the unit configuration (i+3) corresponding to the MSB remains ON, and the switch SW11 of the unit configurations 30_(i+2) to 30_i corresponding to the other bit remains OFF. The switch SW12 of the unit configuration 30_(i+3) corresponding to the MSB remains OFF, and the switch SW11 of the unit configurations 30_(i+2) to 30_i corresponding to the other bit remains ON. Accordingly, the D/A converters DA1 in the row lines (i+2) to i are deactivated, and the output node of the driver DV1 in the row line (i+3) is connected to the input node of the driver DV1 in the row line (i+2). The output node of driver DV1 in the row line (i+2) is connected to the input node of the driver DV1 in the row line (1+1), and the output node of driver DV1 in the row line (i+1) is connected to the input node of driver DV1 in the row line i. The variable gain G of the driver DV1 in the row line (i+3) is set to 1, and the variable gains G of the drivers DV1 in the row lines (i+2) to i are set to 0.5.

Such a configuration enables an analog signal V_{X,0}, which is output from the D/A converter DA1 in the row line (i+3) depending on the input data D_{in,0} , to be transmitted as the input voltage V_{X,0} to unit cell UC_(i+3) of the arithmetic logic operation circuit 20 via the driver DV1 in the row line (i+3). In addition, the analog signal V_{IK},₀ is transmitted to the unit cell UC_(i+2) of the arithmetic logic operation circuit 20 as the input voltage V_{X, 0}/2 via the driver DV1 in the row line (i+3) and the driver DV1 in the row line (i+2). The analog signal V_{X,0} is transmitted as the input voltage V_{X,0}/2² to the unit cell UC_(i+1) of the arithmetic logic operation circuit 20 via the driver DV1 in the row line (i+3), the driver DV1 in the row line (i+2), and the driver DV1 in the row line (i+1). The analog signal V_{X,0} is transmitted as the input voltage V_{X,0}/2³ to the unit cell UC_i of the arithmetic logic operation circuit 20 via the driver DV1 in the row line (i+3), the driver DV1 in the row line (i+2), the driver DV1 in the row line (i+1), and the driver DV1 in the row line i.

The connection configuration illustrated in FIG. 15 makes it possible to reduce the number of D/A converters DA1 operating in the input circuit 2 to one-fourth of the number of rows, decreasing the power consumption of the arithmetic logic operation system 100 including the input circuit 2.

As described above, according to the fifth embodiment, in the arithmetic logic operation system 100, the input circuit 2 is configured by connecting a plurality of unit configurations 30 in a ladder shape. Such a configuration makes it possible to reduce the number of D/A converters DA1 operating in the input circuit 2, decreasing the power consumption of the arithmetic logic operation system 100 including the input circuit 2.

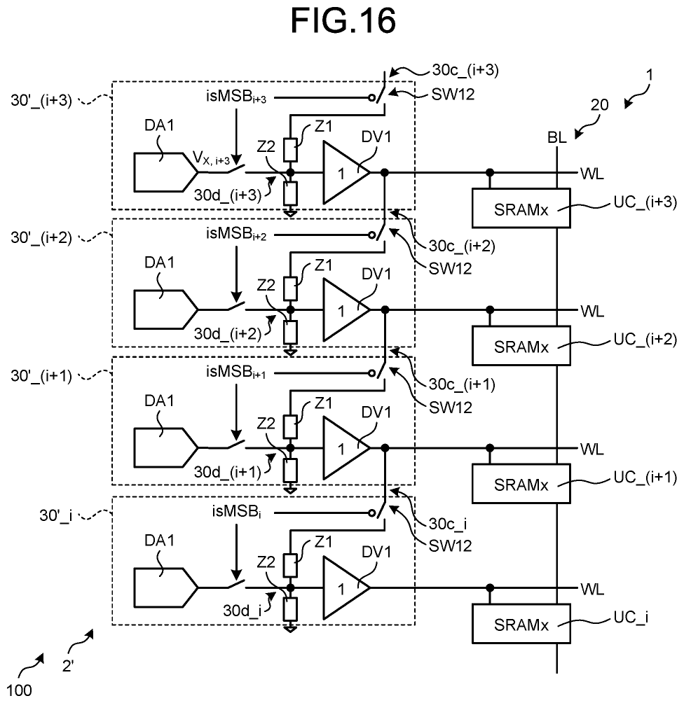

Moreover, each unit configuration 30′ can be configured in such a way that the gain of the driver DV1 is fixed, and the voltage of the input node 30c is divided by a plurality of impedance devices and is input to the driver DV1 as illustrated in FIG. 16. FIG. 16 is a circuit diagram illustrating the configuration of an input circuit 2′ according to a modification of the fifth embodiment.

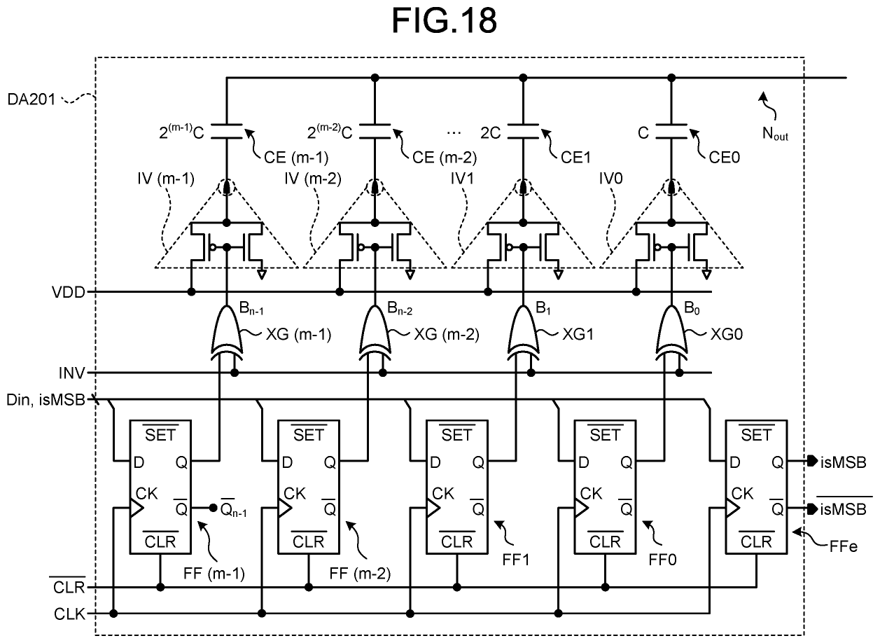

Each of the unit configurations 30′ sets the fixed gain of the driver DV1 to 1 and further has a plurality of impedance devices Z1 and Z2. The plurality of impedance devices Z1 and Z2 has impedance equal to each other. Any device having impedance can be used as each impedance device Z1 and Z2, and for example, a capacitive device, a resistance device, a transistor, or the like can be used. The impedance devices Z1 and Z2 can be shared with some devices in the D/A converter DA1 (e.g., a capacitive device CE, see FIG. 18). In this case, it is possible to reduce the circuit scale of the input circuit 2′.

In each of the unit configurations 30′, the impedance device Z1 has a first end connected to the switch SW12 and a second end connected to the intermediate node 30d. The impedance device Z2 has a first end connected to the intermediate node 30d and a second end connected to a reference potential (e.g., a ground potential).

In one example, in the case where an analog signal V_{X,i+3} is input to the driver DV1 of a unit configuration 30′_(i+3) and the switch SW12 of a unit configuration 30′_(i+2) remains ON, the driver DV1 outputs the analog signal V_{X,i+3}. In addition, the analog signal V_{X,i+3} is divided by the plurality of impedance devices Z1 and Z2 having the unit configuration 30′_(i+2), and the analog signal V_{X,i+3}/2 is input to the driver DV1 having the unit configuration 30′_(i+2). The driver DV1 outputs the analog signal V_{X,i+3}/2.

As described above, the configuration of the input circuit 2′ illustrated in FIG. 16 is also possible to achieve the connection configuration that operates substantially in a similar manner to the connection configuration illustrated in FIGS. 14 and 15. Thus, it is possible to decrease the power consumption of the arithmetic logic operation system 100 including the input circuit 2′.

### Sixth Embodiment

An arithmetic logic operation system 200 according to a sixth embodiment is now described. The configurations different from the first embodiment to the fifth embodiment are hereinafter mainly described.

Although the second embodiment does not describe in detail the configuration of the input circuit of the semiconductor integrated circuit, the sixth embodiment illustrates the specific configuration of the input circuit of the semiconductor integrated circuit.

The arithmetic logic operation system 200 according to the sixth embodiment has an input circuit 202 instead of the input circuit 2 (see FIG. 1) when the multiple bits of the weight W held in the arithmetic logic operation circuit 220 (see FIG. 5) of the semiconductor integrated circuit 201 represent a positive or negative integer in two's complement representation. The input circuit 202 converts the input data Dᵢₙ=(dₘ₋₁, dₘ₋₂, . . . , d₁, d₀) of the digital domain into the input vector X=(V_{COM}−V_{X}, V_{COM}+V_{X}/2, . . . , V_{COM}+V_{X}/2ⁿ⁻², V_{COM}+V_{X}/2ⁿ⁻¹) of the analog domain. The input circuit 202 inputs the converted result to the arithmetic logic operation circuit 220 of the semiconductor integrated circuit 201. It is conceivable to prepare n unit configurations 230_(n−1) to 230_0 as the configuration of the input circuit 202.

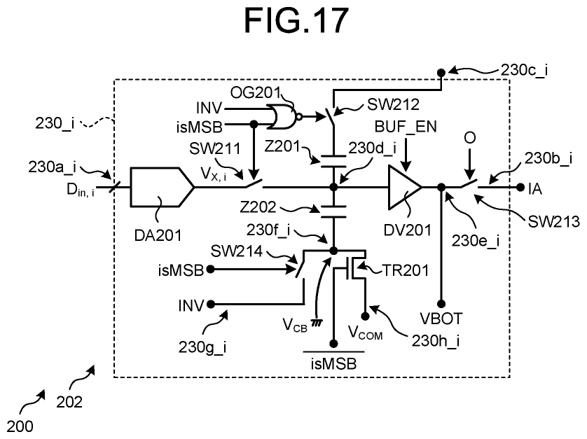

Each of the unit configurations 230 can be configured as illustrated in FIG. 17. FIG. 17 is a diagram illustrating the unit configuration 230 in the input circuit 202, exemplifying a unit configuration 230_i in the row line i (where i=n−1 to 0). In the case where the row line i corresponds to the MSB of the weight W, the unit configuration 230_i generates an input signal Vcom−Vx and inputs it to the arithmetic logic operation circuit 220. In the case where the row line i corresponds to a bit other than the MSB of the weight W, the unit configuration 230_i generates an input signal Vcom+Vx/2ⁿ⁻¹⁻ⁱ and inputs it to the arithmetic logic operation circuit 220.

The unit configuration 230_i has a configuration expanded from the unit configuration 30_i (see FIG. 12). The unit configuration 230_i corresponds to the case where multiple bits of the weight W represent a positive or negative integer in two's complement representation and generates an input voltage having a positive or negative signal amplitude with reference to the common voltage V_{COM} (signal amplitude of zero). The unit configuration 230_i has a D/A converter DA201, a driver DV201, a switch SW211, and a switch SW212 instead of the D/A converter DA1, the driver DV1, the switch SW11, and the switch SW12 (see FIG. 12), respectively. The unit configuration 230_i further includes a switch SW213, a switch SW214, an impedance device Z201, an impedance device Z202, an OR gate OG201, and a transistor TR201.

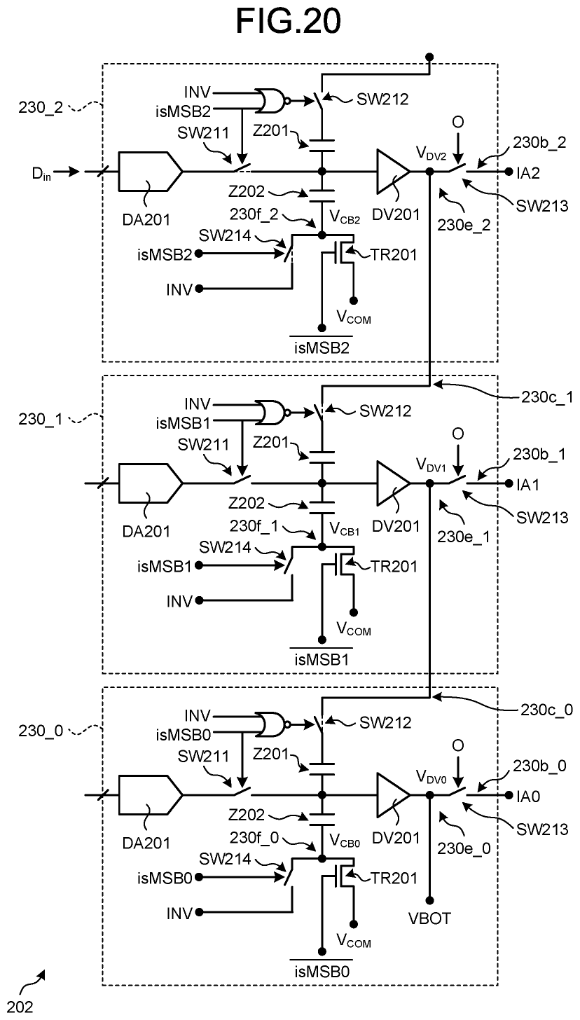

The D/A converter DA201 is electrically connected between an input node 230a_i and the switch SW211. The switch SW211 is electrically connected between the D/A converter DA201 and an intermediate node 230d_i. The driver DV201 is electrically connected between the intermediate node 230d _i and an intermediate node 230e_i. The switch SW212 is electrically connected between an input node 230c_i and the intermediate node 230d_i. The OR gate OG201 performs an OR operation for a global signal INV and the row control signal isMSB and supplies a control terminal of the switch SW212 with the arithmetic logic operation result. The input node 230c_i can be electrically connected to an intermediate node 230e_(i+1) of the unit configuration 230 (i+1) adjacent in the row direction (e.g., one level higher) (see FIG. 20).

Moreover, it is possible to limit the number of the D/A converters DA201, which operate depending on the number of bits n of the weight W by connecting n unit configurations 230_(n−1) to 230_0 in a ladder shape to form the input circuit 202 (see FIG. 20), to 1/n, decreasing the power consumption of the input circuit 202, which is similar to the unit configuration 30 illustrated in FIG. 12.

The switch SW213 is electrically connected between the intermediate node 230e_i and an output node 230b_i. The impedance device Z201 has a first end connected to the switch SW212 and a second end connected to the intermediate node 230d_i. The impedance device Z202 has a first end connected to the intermediate node 230d_i and a second end connected to an intermediate node 230f_i. The impedance devices Z201 and Z202 can employ any device having an impedance. FIG. 17 illustrates a configuration in which the impedance devices Z201 and Z202 are capacitive devices. In this event, the gain of the driver DV1 is fixed to 1, and the plurality of impedance devices Z1 and Z2 have impedance equal to each other.

The switch SW214 is electrically connected between the intermediate node 230f_i and a reference node 230g_i. The reference node 230g_i is supplied with the global signal INV. The transistor TR201 is, for example, an NMOS transistor and has a source connected to a reference node 230h_i, a drain connected to the intermediate node 230f_i, and a gate that receives the row control signal isMSB⁻. The row control signal isMSB⁻is a signal in which the row control signal isMSB is logically inverted. Accordingly, a potential V_{CB} of the intermediate node 230f_i is set to the value of the global signal INV when the row line i corresponds to the MSB of the weight W, and is set to the common voltage V_{COM} when the row line i corresponds to the bit other than the MSB of the weight W.

The D/A converter DA201 of each unit configuration 230 in the case when the bit precision of inputs is m can be configured as illustrated in FIG. 18. FIG. 18 is a circuit diagram illustrating the configuration of the D/A converter DA201.

The D/A converter DA201 is a standard charge redistribution D/A converter. The D/A converter DA201 includes m capacitive devices CE(m−1) to CEO, m inverters IV(m−1) to IVO, m exclusive OR (XOR) gates XG(m−1) to XG0, m flip-flops FF(m−1) to FF0, and a flip-flop FFe. The m flip-flops FF(m−1) to FF0, m exclusive OR gates XG(m−1) to XGO, m inverters IV(m−1) to IVO, and m capacitive devices CE(m−1) to CEO correspond to each other, respectively. Each of m inverters IV(m−1) to IVO includes an NMOS transistor and a PMOS transistor connected to the inverter.

The flip-flop FFe holds the row control signal isMSB in synchronization with a clock CLK. At the same time, the flip-flop FFe outputs the row control signal isMSB to the input node of the OR gate OG201 and the control terminal of the switch SW214, and outputs the row control signal isMSB⁻to the gate of the transistor TR201 (see FIG. 17). The flip-flop FFe resets the held value to an initial value (e.g., 0) when a clear signal CLR⁻reaches the active level (e.g., L level).

The n flip-flops FF(m−1) to FF0 hold the respective values of m bits dₘ₋₁ to d₀ of the input data Dᵢₙ in synchronization with the clock CLK. At the same time, each flip-flop FF outputs the value of bit d to the corresponding exclusive OR gate XG. Each flip-flop FF resets the held value to an initial value (e.g., 0) when a clear signal CLR⁻ reaches the active level (e.g., L level).

The m exclusive OR gates XG(m−1) to XG0 switch whether or not to invert the m bits dₘ₋₁ to d₀ depending on the global signal INV. Each exclusive OR gate XG performs the exclusive OR operation of the bit d received from the corresponding flip-flop FF and the global signal INV to generate arithmetic logic operation results Bₘ₋₁ to B₀. Accordingly, the m exclusive OR gates XG(m−1) to XG0 output m bits dₘ₋₁ to d₀ as the arithmetic logic operation results Bₘ₋₁ to B₀ without any modification to the m inverters IV(m−1) to IV0 in the case of the global signal INV=0. The m exclusive OR gates XG (m−1) to XG0 output the arithmetic logic operation results Bₘ₋₁ to B₀ obtained by bit-inverting the m bits dₘ₋₁ to d₀ to the m inverters IV (m−1) to IV0 in the case of the global signal INV=1.

The m inverters IV (m−1) to IV0 logically invert the m bit values output from the m exclusive OR gates XG(m−1) to XG0 and output them to the m capacitive devices CE(m−1) to CE0. Each inverter IV logically inverts the bit value output from the corresponding exclusive OR gate XG and supplies the first end of the corresponding capacitive device CE.

The m capacitive devices CE (m−1) to CE0 have different capacitance values 2 (m⁻¹)C to C in binary. Each capacitive device CE has a first end connected to the corresponding inverter IV and a second end connected to an output node Nₒᵤₜ. Each capacitive device C accumulates a charge corresponding to the bit value supplied to the first end. In response, the charges at the second ends of the m capacitive devices CE (m−1) to CEO are redistributed depending on the capacitance ratio, and the voltage corresponding to the charges after the redistribution appears at the output node Nₒᵤₜ. Moreover, depending on the control logic, at this time, the switch SW211 illustrated in FIG. 17 can turn ON, so it is also possible to employ the impedance devices (capacitive devices) Z201 and Z202 for charge redistribution.

As the operation of the D/A converter DA201, the following first and second operations can be considered.

In the first operation, the D/A converter DA201 can perform D/A conversion for the input data Din and output V_{COM}+V_{X} as a conversion result from the output node Nₒᵤₜ. The output V_{COM}+V_{X} can vary between 0 V and Vdd=2V_{cam}. The parameter Vx included in the output can have a positive or negative value. In addition, |Vx| can vary between 0 V and V_{COM}. The multiple bits of the input data Din have the MSB as a sign bit. The multiple bits indicate a positive integer when the MSB value is 0 and the multi-bit pattern to be a negative integer when MSB value is 1. Thus, a positive or negative integer represented by the multiple bits of the input data Din can be mapped to the voltage value of the output V_{COM}+V_{X} with a pseudo “binary offset”. In the case where the bit precision n of the D/A converter DA201 is 4 bits, the output V_{COM}+V_{X} can typically vary between V_{COM}−(8/8)×V_{COM} and v_{COM}+(7/8)×V_{COM}.

In the second operation, as expressed in Formulas 4 and 5, in the row corresponding to the MSB of the weight W, the D/A converter DA201 is required to output V_{COM}−V_{X}, and in the row corresponding to the bit other than the MSB of the weight W, the D/A converter DA201 is required to output V_{COM}+V_{X}/2ⁿ⁻ⁱ⁻¹.

The unit configuration 230_i illustrated in FIG. 17 and the D/A converter DA201 illustrated in FIG. 18 are supplied with the global signal INV from the global circuit (see FIG. 5) in such a way as to support both the first operation and the second operation. In the case of the global signal INV=0, the D/A converter DA201 performs the first operation, and the unit configuration 230_i performs the operation corresponding to the first operation of the D/A converter DA201. In the case of the global signal INV=1, the D/A converter DA201 performs the second operation, and the unit configuration 230_i performs the operation corresponding to the second operation of the D/A converter DA201.

In the D/A converter DA201, the m exclusive OR gates XG(m−1) to XG0 perform the exclusive OR operation between the m bits dₘ₋₁ to d₀ and the global signal INV, and the m capacitive devices CE(m−1) to CEO redistribute the charges depending on the capacitance ratio. The first operation is represented by Formula 13 below, and the second operation is represented by Formula (14) below.

[Mathematical 9]

I NV=0:D(X)=V_{COM}+V_{X} Formula 13

I NV=1: ˜D(X)=V_{COM}−V_{X}−1 LSB Formula 14

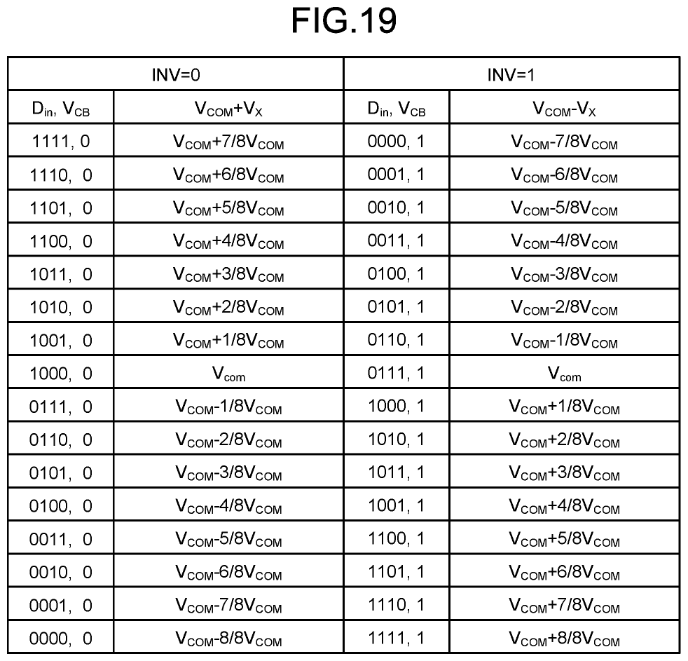

As expressed in Formulas 13 and 14, the second operation has an error by 1 LSB with respect to the first operation. This error of 1 LSB is correctable by using a mapping table, as illustrated in FIG. 19. In FIG. 19, The output V_{COM}+V_{X} or V_{COM}−V_{X} of the D/A converter DA201 is mapped to a set of multiple bits of the input data Dᵢₙ and a bit of the potential V_{CB} of the intermediate node 230f_i for each of the case of the global signal INV=0 and the case of the global signal INV=1. The mapping table illustrated in FIG. 19 makes it possible to align the reference (V_{COM}) between when the global signal INV=0 (the first operation) and when the global signal INV=1 (the second operation), correcting the error of 1 LSB in the second operation.

The arrangement in which the input circuit 202 can be configured by connecting n unit configurations 230_(n−1) to 230_0 in a ladder shape is similar to the fifth embodiment. For any row line i, the input node 230c_i of the unit configuration 230_i is connected to the intermediate node 230e_(i+1) of the unit configuration 230_(i+1) one level higher. The repetition of this connection enables n unit configurations 230_(n−1) to 230_0 to be connected in a ladder shape.

In one example, in the case where the bit precision of the weight W held in the arithmetic logic operation circuit 220 (see FIG. 5) of the semiconductor integrated circuit 201 is n=3 bits and the 3 bits represent a positive or negative integer in two's complement representation, the input circuit 202 can be connected as illustrated in FIG. 20. FIG. 20 is a circuit diagram illustrating the configuration of the input circuit 202, exemplifying a configuration in which the weight W held in the arithmetic logic operation circuit 220 (see FIG. 5) is 3 bits and represents a positive or negative integer by two's complement representation.

An input node 230c_0 of the unit configuration 230_0 is connected to an intermediate node 230e_1 of the unit configuration 230_1 one level higher. An input node 230c_1 of the unit configuration 230_1 is connected to an intermediate node 230e_2 of the unit configuration 230_2 one level higher. Thus, three unit configurations 230_2 to 230_0 can be connected in a ladder shape.

In the ladder-like connection of n unit configurations 230_(n−1) to 230_0, the processing is performed in two phases, and the error of 1 LSB between the unit configurations 230 is correctable by using the global signal INV.

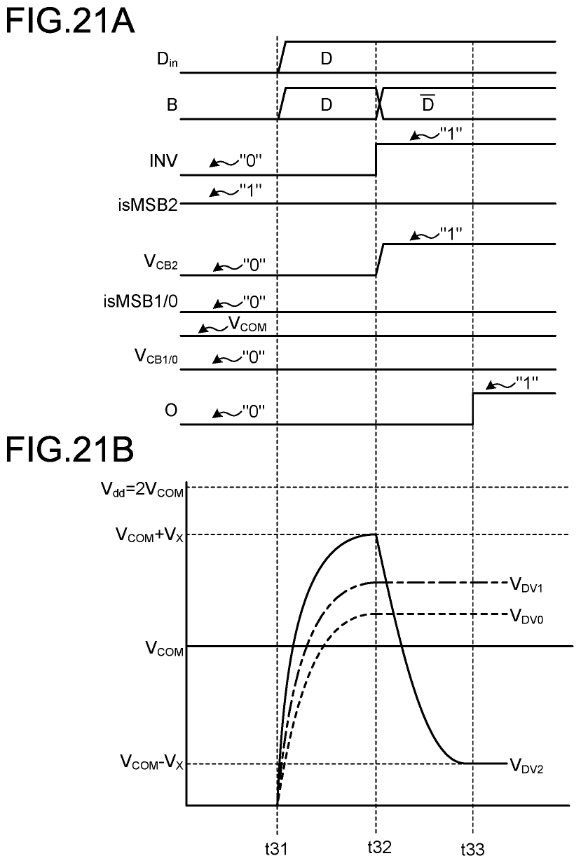

In one example, in the case where the parameter V_{X} has a positive value, the bit precision of the weight W held in the arithmetic logic operation circuit 220 (see FIG. 5) of the semiconductor integrated circuit 201 is n=3 bits, and the 3 bits represent a positive or negative integer of two's complement representation, the input circuit 202 can operate as illustrated in FIGS. 21A and 21B. FIGS. 21A and 21B are waveform diagrams illustrating the operation of the input circuit 202. FIG. 21A illustrates the temporal transition of each signal or each voltage. FIG. 21B illustrates the temporal transition of voltages V_{DV2} to V_{DV0} of intermediate nodes 230e_2 to 230e_0 of three unit configurations 230_2 to 230_0. FIGS. 21A and 21B exemplify the operation of the case where the weight W held in the arithmetic logic operation circuit 220 is 3 bits and represents a positive or negative integer with two's complement representation. It is assumed that the configuration in the D/A converter DA201 also has a configuration corresponding to n=3 (see FIG. 18). Moreover, in the following, the signal level “0” can be read as the L level, and the signal level “1” can be read as the H level.

Immediately before timing t31, the switch SW214 and the transistor TR201 of each unit configuration 230 are controlled to be ON or OFF depending on the values of the row control signals isMSB and isMSB⁻. In other words, the voltage V_{CB} of the intermediate node 230f is set depending on the value of the row control signal isMSB. As illustrated in FIG. 20, in the row line 2 corresponding to MSB of the weight W, the row control signals isMSB2=1, isMSB2⁻=0, the switch SW214 turns ON (the state shown by the dotted line), and the transistor TR201 turns OFF. Thus, a voltage V_{CB1}=V_{COM} is set. In the row line 1 corresponding to the bits other than the MSB of the weight W, the row control signals isMSB1=0 and isMSB1⁻=1, the switch SW214 turns OFF, and the transistor TR201 turns ON. Thus, a voltage V_{CB1}=V_{COM} is set. In the row line 0 corresponding to the LSB of the weight W, the row control signals isMSB0=0 and isMSBO⁻=1, the switch SW214 turns OFF, and the transistor TR201 turns ON. Thus, a voltage V_{CB0}=V_{COM} is set. In this event, a control signal O=0 for the switch SW213 remains. Thus, the switch SW213 turns OFF.

The switches SW211 and SW212 of each unit configuration 230 are controlled to be ON or OFF depending on the values of the row control signals isMSB and isMSB⁻. In the row line 2 corresponding to the MSB of the weight W, the row control signals isMSB2=1 and isMSB2⁻=0, the switch SW211 turns ON (the state shown by the dotted line), and the switch SW212 turns OFF. Thus, the D/A converter DA201 is activated. In the row line 1 corresponding to the bits other than the MSB of the weight W, the row control signals isMSB1=0 and isMSB1⁻=1, the switch SW211 turns OFF, and the switch SW212 turns ON (the state shown by the dotted line). Thus, the converter DA201 is deactivated, and the intermediate node 230e_2 in the row line 2 is connected to the first end of the impedance device Z201. In the row line 0 corresponding to the LSB of the weight W, the row control signals isMSB0=0 and isMSB0⁻=1, the switch SW211 turns OFF, and the switch SW212 turns ON (the state shown by the dotted line). Thus, the D/A converter DA201 is deactivated and the intermediate node 230e_2 in the row line 1 is connected to the first end of the impedance device Z201. Accordingly, a ladder-like connection configuration of the D/A converter DA201 of the unit configuration 230_2 → the switch SW211 → the driver DV201 the impedance device Z201 of the unit configuration 230_1 → the driver DV201 → the impedance device Z201 of the unit configuration 230_0 the driver DV201 is formed. In addition, it is possible to limit the number of D/A converters DA201 operating in the unit configurations 230_2 to 230_0 to one, decreasing the power consumption of the input circuit 202.

As illustrated in FIGS. 21A and 21B, the processing of the first phase is performed during the period from timings t31 to t32. At timing t31, the input data Din=(d₂, d₁, d₀) is input to the D/A converter DA201 of the unit configuration 230_2, and 3 bits d₂ to d₀ are held in three flip-flops FF2 to FF0, respectively. The global signal INV=0, so three exclusive OR gates XG2 to XG0 output 3 bits d₂ to d₀ without any modification to three inverters IV2 to IV0 as arithmetic logic operation results B₂ to B₀, respectively. The three inverters IV2 to IV0 logically invert the arithmetic logic operation results B₂ to B₀ and supply the first ends of the three capacitive devices CE2 to CE0, respectively. At the first ends of the three capacitive devices CE2 to CE0, the charges corresponding to the logical inversion values of the arithmetic logic operation results B₂ to B₀ are generated. At the second end, the charges of opposite polarities are generated accordingly. The charges generated at the second end are redistributed depending on the ratio of capacitance values 2²C, 2C, and C of the three capacitive devices CE2, CE1, and CE0.

Thus, the voltage of the output node Nₒᵤₜ of the D/A converter DA201 of the unit configuration 230_2 gradually increases from 0 V to V_{COM}+V_{X}, and the voltage V_{DV2} of the intermediate node 230e_2 of the unit configuration 230_2 gradually increases from 0 V to V_{COM}+V_{X}. Accordingly, a voltage V_{DV1} of the intermediate node 230e_1 of the unit configuration 230_1 gradually increases from 0 V to V_{COM}+V_{X}/2 due to the voltage division of the impedance devices Z201 and Z202 of the unit configuration 230_1. Furthermore, the voltage V_{DV0} of the intermediate node 230e_0 of the unit configuration 230_0 gradually increases from 0 V to V_{COM}+V_{X}/2² due to the voltage division of the impedance devices Z201 and Z202 of the unit configuration 230_0. In this event, the control signal O is maintained to be 0.

During the period from timings t32 to t33, the processing of the second phase is performed. At timing t32, the global signal INV shifts from 0 to 1, so the voltage V_{CB2} shifts from 0 to 1. Accordingly, to correct the error of 1 LSB, the exclusive OR gates XG2 to XG0 in the D/A converter DA201 of the unit configuration 230_2 output three operation results B₂ to B₀ obtained by bit-inverting the 3 bits d₂ to d₀ to the three inverters IV2 to IV0, respectively. In addition, this causes the voltage of the output node Nₒᵤₜ of the D/A converter DA201 of the unit configuration 230_2 to decrease from V_{COM}+V_{X} to V_{COM}−V_{X} gradually and the voltage V_{DV2} of the intermediate node 230e_2 of the unit configuration 230_2 to decrease from V_{COM}+V_{X} to V_{COM}−V_{X} gradually.

On the other hand, the switch SW212 of the unit configuration 230_1 and the switch SW212 of the unit configuration 230_0 turn OFF depending on the global signal INV=1 (the state shown by the solid line in FIG. 20). In addition, the unit configuration 230_1 remains at the voltage V_{CB1}=V_{COM}, so the voltage V_{DV1} of the intermediate node 230e_1 is maintained at V_{COM}+V_{X}/2. Similarly, the unit configuration 230_0 maintains the voltage V_{CB0}=V_{COM}, so the voltage V_{DV0} of the intermediate node 230e_0 in the unit configuration 230_0 remains at V_{COM} +V_{X}/2². In this event, the control signal 0 is maintained to be 0.

At timing t33, the control signal O shifts from 0 to 1. In each of the unit configurations 230_2 to 230_0, the switch SW213 turns ON, and the voltage of the intermediate node 230e is transmitted to the output node 230b. This causes the unit configuration 230_2 to input the input voltage V_{COM}−V_{X} to the arithmetic logic operation circuit 220, the unit configuration 230_1 to input the input voltage V_{COM}+V_{X}/2 to the arithmetic logic operation circuit 220, and the unit configuration 230_0 to input the input voltage V_{COM}+V_{X}/2′ to the arithmetic logic operation circuit 220 (see FIG. 5).

As described above, according to the sixth embodiment, in the arithmetic logic operation system 200, the input circuit 202 is configured by connecting a plurality of unit configurations 230 in a ladder shape. Such a configuration makes it possible to reduce the number of D/A converters DA201 operating in the input circuit 202, decreasing the power consumption of the arithmetic logic operation system 200 including the input circuit 202.

Moreover, mapping the output voltage to the set of the multiple bits b of the input data Dᵢₙ and the bits of the V_{CB} in the D/A converter DA201 is not limited to the example illustrated in FIG. 19, and any mapping using the common voltage V_{COM} as a reference can be used.

Further, there may be the case where the input circuit 202 is configured as the ladder-like connection of n unit configurations 230 (n−1) to 230_0. In this case, a configuration in which the power supply to the driver DV201 is stopped and the switch SW213 remains OFF can be provided in the unit configuration 230 in the row corresponding to the bit value 0 of the input data Dᵢₙ. This makes it possible to decrease the power consumption of the input circuit 202.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a plurality of storage devices arranged in a form of a plurality of rows, each of the storage devices being configured to store a bit position value of a weight of multiple bits;
a plurality of multiplication circuits arranged in a form of a plurality of rows and configured to multiply a plurality of input voltages by the weight of multiple bits to generate a plurality of multiplication results;
one or more capacitive devices configured to accumulate charges corresponding to the plurality of multiplication results; and
an adder circuit configured to generate an output voltage corresponding to the total value of the charges accumulated in the one or more capacitive devices,
wherein the plurality of input voltages have different amplitudes, each of the input voltages being associated with a corresponding bit position of the weight.

2. The semiconductor integrated circuit according to claim 1,
wherein the adder circuit is configured to redistribute the charges accumulated in the one or more capacitive devices among the one or more capacitive devices to generate a voltage corresponding to the redistributed charges as the output voltage.

3. The semiconductor integrated circuit according to claim 2,
wherein an amount of the redistributed charges includes an amount of a charge obtained by averaging an amount of the charges accumulated in the one or more capacitive devices among the one or more capacitive devices.

4. The semiconductor integrated circuit according to claim 1,
wherein the adder circuit is configured to add the charges accumulated in the one or more capacitive devices to generate a voltage corresponding to an added charges as the output voltage.

5. The semiconductor integrated circuit according to claim 4,
wherein an amount of the added charges includes an amount of a charge obtained by summing an amount of the charges accumulated in the one or more capacitive devices among the one or more capacitive devices.

6. The semiconductor integrated circuit according to claim 1,
wherein a pattern of the multiple bits included in the weight represents a positive integer, and
each of the plurality of input voltages is associated with a corresponding bit of the multiple bits and has a positive amplitude different from an amplitude of an input voltage corresponding to an adjacent bit by a power of 2.

7. The semiconductor integrated circuit according to claim 1,
wherein the pattern of the multiple bits included in the weight represents a positive or negative integer in two's complement representation, and
each of the plurality of input voltages is associated with a corresponding bit of the multiple bits and has a positive or negative amplitude different from an amplitude of an input voltage corresponding to an adjacent bit by a power of 2.

8. The semiconductor integrated circuit according to claim 1,
wherein the one or more capacitive devices have respective first ends,
each of the plurality of multiplication circuits has an input node, one capacitive device of the one or more capacitive devices, a first switching device, and a second switching device, the first switching device turning ON or OFF depending on a first global signal, the second switching device being connected in series with the first switching device between the input node and the first end of the one capacitive device and being maintained ON or OFF depending on a bit value of the weight, and
the adder circuit includes an output node, a third switching device, and a plurality of fourth switching devices, the third switching device being provided between a common voltage having a reference potential and the first end of the one capacitive device of the one or more capacitive devices and turning ON or OFF depending on a second global signal, and each of the plurality of fourth switching devices being provided between the first end of each of the one or more capacitive devices and the output node and turning ON or OFF depending on a third global signal.

9. The semiconductor integrated circuit according to claim 8,
wherein the semiconductor integrated circuit is configured to:
maintain the plurality of first switching devices OFF and maintain the third switching device and the plurality of fourth switching devices ON in a first period,
maintain the plurality of first switching devices ON and maintain the third switching device and the plurality of fourth switching devices OFF in a second period after the first period, and
maintain the plurality of first switching devices and the third switching device OFF and maintain the plurality of fourth switching devices ON in a third period after the second period.

10. The semiconductor integrated circuit according to claim 1,
wherein the one or more capacitive devices are arranged in a form of a plurality of rows and a plurality of columns,
the plurality of multiplication circuits is arranged in a form of a plurality of rows and a plurality of columns, and
a plurality of the adder circuits are configure to generate a plurality of output voltages corresponding to the total value of charges accumulated in a capacitive device in each column among the one or more capacitive devices.

11. The semiconductor integrated circuit according to claim 10, wherein
the adder circuit is configure to redistribute charges accumulated in the capacitive devices in a first column among the capacitive devices in the first column and generate a voltage corresponding to the charges redistributed in the first column as the output voltage of the first column, and
the adder circuit is configure to redistribute charges accumulated in the capacitive devices in a second column among the capacitive devices in the second column and generate a voltage corresponding to the charges redistributed in the second column as the output voltage of the second column.

12. The semiconductor integrated circuit according to claim 10, wherein
the adder circuit is configure to add the charges accumulated in the capacitive devices in the first column to generate a voltage corresponding to the charges added in the first column as the output voltage of the first column, and
the adder circuit is configure to add the charges accumulated in the capacitive devices in the second column to generate a voltage corresponding to the charges added in the second column as the output voltage of the second column.

13. An arithmetic logic operation system comprising:
an input circuit configured to convert data of multiple bits into a plurality of voltages; and
the semiconductor integrated circuit of claim 1 configured to receive the plurality of converted voltages as the plurality of input voltages.

14. The arithmetic logic operation system according to claim 13, wherein
a pattern of the multiple bits included in the weight represents a positive integer, and
each of the plurality of input voltages is associated with a corresponding bit of the multiple bits and has a positive amplitude different from an amplitude of an input voltage corresponding to an adjacent bit by a power of 2.

15. The arithmetic logic operation system according to claim 13,
wherein the pattern of the multiple bits included in the weight represents a positive or negative integer in two's complement representation, and
each of the plurality of input voltages is associated with a corresponding bit of the multiple bits and has a positive or negative amplitude different from an amplitude of an input voltage corresponding to an adjacent bit by a power of 2.

16. The arithmetic logic operation system according to claim 13,
wherein the one or more capacitive devices have respective first ends,
each of the plurality of multiplication circuits has an input node, one capacitive device of the one or more capacitive devices, a first switching device, and a second switching device, the first switching device turning ON or OFF depending on a first global signal, the second switching device being connected in series with the first switching device between the input node and the first end of the one capacitive device and being maintained ON or OFF depending on a bit value of the weight, and
the adder circuit includes an output node, a third switching device, and a plurality of fourth switching devices, the third switching device being provided between a common voltage having a reference potential and the first end of the one capacitive device of the one or more capacitive devices and turning ON or OFF depending on a second global signal, and each of the plurality of fourth switching devices being provided between the first end of each of the one or more capacitive devices and the output node and turning ON or OFF depending on a third global signal.

17. The arithmetic logic operation system according to claim 13,
wherein the one or more capacitive devices are arranged in a form of a plurality of rows and a plurality of columns,
the plurality of multiplication circuits is arranged in a form of a plurality of rows and a plurality of columns, and
a plurality of the adder circuits are configure to generate a plurality of output voltages corresponding to the total value of charges accumulated in a capacitive device in each column among the one or more capacitive devices.

18. The arithmetic logic operation system according to claim 13,
wherein the input circuit has a plurality of unit configurations corresponding to the multiple bits, and
each of the plurality of unit configurations includes a driver.

19. The arithmetic logic operation system according to claim 18,
wherein each of the plurality of unit configurations further includes:
an A/D converter;
a fifth switching device having a first end connected to the A/D converter and a second end connected to the driver; and
a sixth switching device having a first end connected to an output node of the driver of another unit configuration and a second end connected to an input node of the driver thereof.

20. The arithmetic logic operation system according to claim 19,
wherein the input circuit is configured to maintain the fifth switching device ON and the sixth switching device OFF in a first unit configuration corresponding to a most significant bit (MSB) of data among the plurality of unit configurations, and the input circuit is configured to maintain the fifth switching device OFF and the sixth switching device ON in a second unit configuration corresponding to a bit other than the MSB of the data among the plurality of unit configurations.
